(19) United States
(12) Patent Application Publication
(10) Pub. No.: US 2026/0222005 A1
(43) Pub. Date: Jul. 30, 2026

(54) METHODS AND APPARATUS TO TRANSMIT A SERIAL DATA STREAM

(71) Applicant: Texas Instruments Incorporated, Dallas, TX (US)

(72) Inventors: Neeka Nikfar, Saratoga, CA (US); Ashwin Ramachandran, Santa Clara, CA (US); Surya Theja Golakonda, Sunnyvale, CA (US); Ramsin Ziazadeh, San Jose, CA (US); Anirudh Rustagi, San Jose, CA (US)

(21) Appl. No.: 19/041,473

(22) Filed: Jan. 30, 2025

(51) Int. Cl. H04B 3/20; H03F 3/19; H04B 1/10; H04L 25/03

(52) U.S. Cl. CPC H04B 3/20; H03F 3/19; H04B 1/10; H04L 25/03019

(57) ABSTRACT

An example apparatus includes: filter circuitry having a first output and a second output; source follower circuitry having a first input, a second input, and an output, the first input of the source follower circuitry coupled to the first output of the filter circuitry, the second input of the source follower circuitry coupled to the second output of the filter circuitry; a resistor having a first terminal and a second terminal; load circuitry having an input and an output, the input of the load circuitry coupled to the output of the source follower circuitry and the first terminal of the resistor; and combination circuitry having a first input, and a second input, the first input of the combination circuitry coupled to the second terminal of the resistor, the second input of the combination circuitry coupled to the output of the load circuitry.

### TECHNICAL FIELD

This description relates generally to transmitter circuitry and, more particularly, to methods and apparatus to transmit serial data stream.

### BACKGROUND

In communication systems, multiple devices exchange data by transmitting and receiving signals. Such devices include transmitter circuitry and receiver circuitry. The transmitter circuitry transmits signals to the receiver circuitry of another device across a communication channel. In full-duplex communication systems, multiple devices may transmit signals along the communication channel simultaneously. In operation, the transmitter circuitry of different devices utilize additional circuitry to support simultaneous communications.

### SUMMARY

For methods and apparatus to a transmit serial data stream, an example apparatus includes filter circuitry having a first output and a second output; source follower circuitry having a first input, a second input, and an output, the first input of the source follower circuitry coupled to the first output of the filter circuitry, the second input of the source follower circuitry coupled to the second output of the filter circuitry; a resistor having a first terminal and a second terminal; load circuitry having an input and an output, the input of the load circuitry coupled to the output of the source follower circuitry and the first terminal of the resistor; and combination circuitry having a first input, and a second input, the first input of the combination circuitry coupled to the second terminal of the resistor, the second input of the combination circuitry coupled to the output of the load circuitry. Other examples are described.

For methods and apparatus to a transmit serial data stream, an example apparatus includes receiver circuitry having an input; transmitter circuitry having a first output, a second output, a third output, and a fourth output; and echo cancelation circuitry including: load circuitry having a first input, a second input, a first output and a second output, the first input of the load circuitry coupled to the first output of the transmitter circuitry, the second input of the load circuitry coupled to the second output of the transmitter circuitry; and combination circuitry having a first input, a second input, a third input, a fourth input, and an output, the first input of the combination circuitry coupled to the third output of the transmitter circuitry, the second input of the combination circuitry coupled to the fourth output of the transmitter circuitry, the third input of the combination circuitry coupled to the first output of the load circuitry, the fourth input of the combination circuitry coupled to the second output of the load circuitry, the output of the combination circuitry coupled to the input of the receiver circuitry. Other examples are described.

For methods and apparatus to a transmit serial data stream, an example apparatus includes first transmitter circuitry having an output; a communication channel having a first terminal and a second terminal, the first terminal of the communication channel coupled to the output of the first transmitter circuitry; second transmitter circuitry having a first output and a second output; echo cancelation circuitry having a first input, a second input, and an output, the first input of the echo cancelation circuitry coupled to the first output of the second transmitter circuitry, the second input of the echo cancelation circuitry coupled to the second terminal of the communication channel and the second output of the second transmitter circuitry; and receiver circuitry having an input coupled to the output of the echo cancelation circuitry. Other examples are described.

### BRIEF DESCRIPTION OF THE DRAWINGS

FIG. 1 is a block diagram of an example vehicle including an example advanced driver-assistance (ADAS) system and an example in-vehicle infotainment (IVI) system.

FIG. 2 is a block diagram of an example of the ADAS system of FIG. 1 including example deserializer circuitry and example serializer circuitry.

FIG. 3 is a block diagram of an example of the IVI system of FIG. 1 including example serializer circuitry, and example deserializer circuitry.

FIG. 4 is a block diagram of an example of the deserializer circuitry of FIGS. 2 and 3 including example back-channel transmitter circuitry.

FIG. 5 is a block diagram of an example of the serializer circuitry of FIGS. 2 and 3 including example front-channel transmitter circuitry.

FIG. 6 is a block diagram including examples of the serializer and deserializer circuitry of FIGS. 2, 3, 4, and 5, which may be referred to as a serial-deserializer (SerDes) system.

FIG. 7 is a block diagram of an example of the back-channel transmitter circuitry of FIGS. 4 and 6.

FIG. 8 is a schematic diagram of an example of the back-channel transmitter circuitry of FIGS. 4, 5, 6, and 7 including example AC coupler circuitry, example filter circuitry, and example source follower circuitry.

FIG. 9 is a schematic diagram of an example of the AC coupler circuitry of FIG. 8.

FIG. 10 is a flowchart representative of example machine-readable instructions or example operations that may be at least one of executed, instantiated, or performed using an example implementation of the back-channel transmitter circuitry of FIGS. 4, 5, 6, 7, 8, and 9.

FIGS. 11A and 11B are plots of example operations of the back-channel transmitter circuitry of FIGS. 4, 5, 6, 7, and 8.

FIG. 12 is a block diagram of an example of the front-channel transmitter circuitry of FIGS. 5 and 6.

FIG. 13 is a schematic diagram of an example of the front-channel transmitter circuitry of FIGS. 5, 6, and 12.

FIG. 14 is a schematic diagram of another example of the front-channel transmitter circuitry of FIGS. 5, 6, 12, and 13.

FIG. 15 is a flowchart representative of example machine-readable instructions or example operations that may be at least one of executed, instantiated, or performed using an example implementation of the front-channel transmitter circuitry of FIGS. 5, 6, 12, 13, and 14.

FIG. 16 is a plot of example operations of the front-channel transmitter circuitry of FIGS. 5, 6, 12, 13, and 14.

The drawings are not necessarily to scale. Generally, the same reference numbers in the drawing(s) and this description refer to the same or similar (functionally and/or structurally) features and/or parts. Although the drawings show regions with clean lines and boundaries, some or all of these lines and boundaries may be idealized. In reality, the boundaries or lines may be unobservable, blended or irregular.

### DETAILED DESCRIPTION

In communication systems, multiple devices exchange data by transmitting and receiving signals. Such devices include transmitter circuitry and receiver circuitry. The transmitter circuitry transmits signals to the receiver circuitry of another device across a communication channel. In full-duplex communication systems, multiple devices may transmit signals along the communication channel simultaneously. In operation, the transmitter circuitry of different devices utilizes additional circuitry to support simultaneous communications.

The transmitter circuitry drives the communication channel using driver circuitry. One type of driver circuitry is source-series terminated (SST) driver circuitry. SST driver circuitry includes an inverter, a resistor-capacitor (RC) filter, a high-side transistor, a high-side resistor, a low-side transistor, and low-side resistor. The inverter drives the RC filter by inverting a digital input signal. The RC filter controls the high and low side transistors responsive to the inverted digital input signal. The high-side transistor and resistor pull-up the communication channel responsive to a logical one (e.g., logic high) of the digital input signal, which is a logical zero (e.g., logic low) of the inverted digital input signal. The low-side transistor and resistor pull-down the communication channel responsive to a logical zero of the digital input signal, which is a logical one of the inverted digital input signal.

In operation, the transconductance of the high-side transistor and the resistance of the high-side resistor impedance match the communication channel. Similarly, the transconductance of the low-side transistor and the resistance of the low-side resistor are structured to impedance match the communication channel. However, return loss is dependent on the load parasitic of the communication channel responsive to using the high and low side transistors to impedance match the communication channel. Also, process variations between the high and low side components creates mismatch between rise and fall times of transmitted signals. Such mismatch distorts transmissions.

Another type of driver circuitry is current-mode-logic (CML) driver circuitry. CML driver circuitry includes a resistor-capacitor (RC) filter to control a pair of transistors. The pair of transistors drive the communication channel by sinking current from load resistors. For example, the transistors pull-down the communication channel responsive to sinking current through the load resistors. Alternatively, the load resistors pull-up the communication channel responsive to a lack of current through the transistors.

In operation, the load resistors are structured to impedance match the communication channel. However, when the transistors are pulling down the communication channel, the impedance matching is altered by the impedance of the transistors responsive to the magnitude of current being sunk. Such changes in the impedance of the CML driver circuitry distorts the transmitted signal responsive to non-ideal impedance matching. Also, differences between the impedances of the transistors and the load resistors create a mismatch between rise and fall times of the transmitted signal.

Some CML driver circuitry include multiple pairs of transistors coupled in parallel to drive the load resistors. The multiple pairs of transistors implement feed-forward equalization (FFE). During transmission of a logical one, the CML driver circuitry sequences turning off each pair of transistors to create an amplitude that steps down over time. This step down of the amplitude over time adds a high frequency element to the transmitted signal, which the communication channel can attenuate to create a steep fall off. Such a step down of the amplitude of a digital pulse over time for transmission is referred to as FFE.

In operation, the steep roll off reduces bit errors of the receiver circuitry and improves inter-symbol interference (ISI). However, return loss is limited responsive to the parasitic capacitances of the multiple pairs of parallel transistors. To account for return loss at high frequencies, some designs include inductors between the load resistors and the communication channel. Such inductors increase the system on chip (SoC) size and cost of implementing FFE. Also, sequencing the sinking of currents by the transistors increases the mismatch between rise and fall times responsive to changes in the pull-down impedance as pairs of transistors turn off.

In both CML and SST driver circuitry, transitions between rising and falling edges are distorted by the transition from the impedance matching by high-side and low-side components. Such distortions limit the linearity of the transmitter circuitry. In some designs, the limited linearity of the transmitter circuitry may limit different methods of signaling, such as pulse amplitude modulation (PAM) signaling. In full duplex communication systems, both CML and SST driver circuitry may have to sink and source current to support simultaneous communications. In such systems, the currents of the simultaneous communications may produce a bias that distorts the output impedance of the CML and SST driver circuitry.

In full duplex communication systems, some devices also include echo cancellation circuitry, which removes transmitted signals from a main signal path, such as signals of the communication channel. The echo cancellation circuitry provides the remaining portions of communication signals to the receiver circuitry. In operation, the remaining portions of the communication signals represent data transmitted by another device across the communication channel. The echo cancelation circuitry improves signal integrity by reducing the contributions of transmitted signals to signals at the input of the receiver circuitry.

Some devices implement echo cancelation using primary transmitter circuitry and secondary transmitter circuitry. The primary transmitter circuitry transmits signals by driving the communication channel. The secondary transmitter circuitry includes internal termination circuitry, which replicates the impedance of the communication channel. The secondary transmitter circuitry generates a replica of the transmitted signal of the primary transmitter circuitry responsive to driving the internal termination circuitry.

However, mismatches between impedances of the internal termination circuitry and the communication channel degrade echo cancellation. For example, at relatively high frequencies, impedances of the communication channel attenuate signal strength. In such examples, the receiver circuitry amplifies communication signals to counter the attenuation along the communication channel. The receiver circuitry may amplify portions of the transmitted signal responsive to mismatches between the impedance of termination circuitry and the communication channel. Also, process variations between the primary and secondary transmitter circuitry further increase inaccuracies in echo cancelation.

Examples described herein include methods and apparatus to transmit a serial data stream. In some described examples, a device that supports full-duplex communications includes transmitter circuitry, echo cancellation circuitry, and receiver circuitry. In such examples, the transmitter circuitry further includes alternative current (AC) coupler circuitry, filter circuitry, source follower circuitry, and resistors. The transmitter circuitry drives a communication channel and produces a replica of the transmitted signal. In operation, the AC coupler circuitry sets a common mode voltage of a digital input signal. Also, the AC coupler circuitry may scale (e.g., attenuate, amplify, etc.) the digital input signal. For example, the AC coupler circuitry may scale multiple digital input signals to implement PAM signaling. The filter circuitry is a second order filter, which converts the AC coupled digital signal into a sinusoidal signal. The source follower circuitry uses a positive feedback path to control cross-coupled transistors, which reduces impedance loss from parasitic capacitances of the communication channel. The source follower circuitry includes an additional capacitance to increase the impedance matching across a larger bandwidth. Also, the positive feedback path of the source follower circuitry compensates for current of simultaneous communications to maintain the output impedance and signal integrity. The source follower circuitry provides the load transistors current to drive the communication channel.

The echo cancelation circuitry further includes impedance matching circuitry and combination circuitry. The impedance matching circuitry is coupled to the outputs of the source follower circuitry. Advantageously, the positive feedback path of the source follower circuitry compensates for the additional load of the impedance matching circuitry. The impedance matching circuitry produces a replica of the transmitted signal responsive to matching the scaling of the transmitted signal by the load resistors of the transmitter circuitry. The combination circuitry subtracts the replica of the transmitted signal from the signals of the communication channel. Advantageously, the transmitter circuitry allows the echo cancellation circuitry to remove the transmitted signal from signals of the communication channel without a replica transmitter. Advantageously, using a replica from the transmitter circuitry reduces mismatch in echo cancellation. Advantageously, using a replica from the transmitter circuitry reduces the system on chip (SoC) size of echo cancelation circuitry responsive to no longer needing a secondary transmitter.

In other described examples, the transmitter circuitry includes a plurality of FFE segments, cross-coupled transistors, and load resistors. In such examples, the plurality FFE segments further include capacitor voltage dividers, bias resistors, and transistor pair. In operation, the capacitor voltage divider divides the amplitude of the digital input signal to set the weight of the step down of the amplitude of each FFE segment. The transistor pair sinks current from the cross-coupled transistors responsive to the stepped-down amplitudes of the digital input signal.

The cross-coupled transistors isolate capacitances of the plurality of FFE segments by creating a virtual ground. The virtual ground provides a node (e.g., a terminal) for currents of the plurality of FFE segments to combine without changing the voltage of the communication channel. The cross-coupled transistors sink current from the load resistors to pull-down the communication channel. Alternatively, the load resistors pull-up the communication channel responsive to a lack of current from the resistors. Advantageously, the cross-coupled positive feedback loop achieves active impedance compensation and matched rise/fall time without compromising speed or FFE tunability.

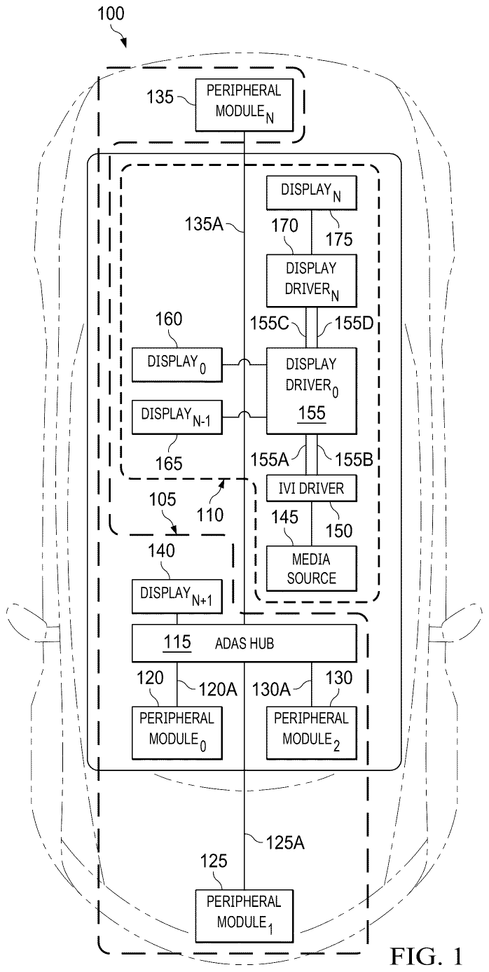

FIG. 1 is a block diagram of an example vehicle 100 including an example advanced driver-assistance (ADAS) system 105 and an example in-vehicle infotainment (IVI) system 110. The ADAS system 105 and the IVI system 110 may be referred to as flat panel display (FPD) link systems that may display media, such as images, multi-media content, etc. In some examples, the vehicle 100 may include one or more instances of the ADAS system 105 or the IVI system 110. For example, the vehicle 100 may include one or more instances of the ADAS system 105 without the IVI system 110. In another example, the vehicle 100 may include one or more instances of the IVI system 110 without the ADAS system 105. In yet another example, the vehicle 100 may include one or more instances of the ADAS system 105 and one or more instances of the IVI system 110. In the example of FIG. 1, the vehicle 100 is illustrated as a system for traversing distances, such as a car, a truck, etc. Alternatively, the vehicle 100 may be replaced, illustrated, or described as an alternative distributed display system, such as a boat, airplane, spacecraft, workstation, control panel, etc.

The ADAS system 105 of FIG. 1 includes an example ADAS hub 115, a first example peripheral module 120, a second example peripheral module 125, a third example peripheral module 130, a fourth example peripheral module 135, and an example display 140.

Alternatively, the ADAS system 105 may include any number of peripheral module(s) or display(s).

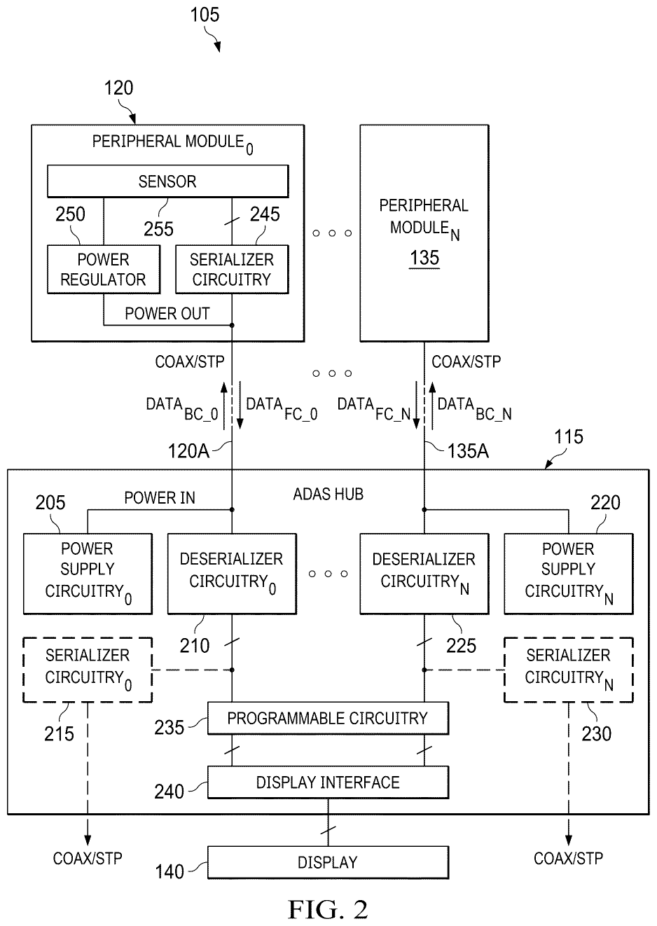

The ADAS system 105 is an example type of FPD-link system that utilizes serializing and deserializing data for driving assistance in the vehicle 100. In some examples, the ADAS system 105 utilizes serializing and deserializing media for an alternative implementation of processing, storing, or displaying data, such as a security system, recording system, etc. In some examples, the ADAS system 105 is an example camera system that facilitates at least one of the storing, processing, or displaying multi-media data (e.g., images, videos, etc.) from one or more sensors, such as cameras. In other examples, the ADAS system 105 may facilitate at least one of the storing, processing, or displaying an alternative type of data from one or more alternative types of sensors (e.g., lidar, radar, ultrasonic, etc.). An example of the ADAS system 105 is further illustrated and described in connection with FIG. 2.

The ADAS hub 115 is communicatively coupled to the peripheral modules 120, 125, 130, 135 and the display 140. The ADAS hub 115 uses full duplex communications to transmit data to and receive data from the peripheral modules 120, 125, 130, 135. In some examples, the ADAS hub 115 uses low-voltage differential signaling (LVDS) to communicate with the peripheral modules 120, 125, 130, 135. Alternatively, the ADAS hub 115 may use an alternative type of signaling to communicate with the peripheral modules 120, 125, 130, 135, such as display serial interface (DSI), embedded display port (eDP), etc. The ADAS hub 115 may at least one of store, process, or display data from the peripheral modules 120, 125, 130, 135. In the example of FIG. 1, the ADAS hub 115 displays the data from one or more of the peripheral modules 120, 125, 130, 135 using the display 140. The ADAS hub 115 uses multi-lane signaling to display data using the display 140. Also, the ADAS hub 115 may also at least one of store or process data from the peripheral modules 120, 125, 130, 135 for other functions of the vehicle 100, such as object recognition, time of flight calculations, etc. An example of the ADAS hub 115 is further illustrated and described in connection with FIG. 2.

The peripheral modules 120, 125, 130, 135 are communicatively coupled to the ADAS hub 115. The peripheral modules 120, 125, 130, 135 include at least one sensor that receives information of the surrounding environment, such as images, videos, time of flight measurements, beamforming data, etc. The peripheral modules 120, 125, 130, 135 transmit the received sensor data to the ADAS hub 115 using communication channels 120A, 125A, 130A, 135A. In some examples, the communication channels 120A, 125A, 130A, 135A are coaxial connectors, which couple the ADAS hub 115 to the peripheral modules 120, 125, 130, 135. In such examples, the ADAS hub 115 supplies power to the peripheral modules 120, 125, 130, 135 using power over coax (POC) across the communication channels 120A, 125A, 130A, 135A. Alternatively, the communication channels 120A, 125A, 130A, 135A may be formed by a different type of connector, such as a standard twisted pair (STP). An example of the peripheral modules 120, 125, 130, 135 are further illustrated and described in connection with FIG. 2.

In example operation of the ADAS system 105 of FIG. 1, the peripheral modules 120, 125, 130, 135 produce video streams of the environment surrounding the vehicle 100. The peripheral modules 120, 125, 130, 135 serialize data of the video streams. The peripheral modules 120, 125, 130, 135 transmit the serial data streams to ADAS hub 115 using the communication channels 120A, 125A, 130A, 135A. Concurrently, the ADAS hub 115 may transmit data to the peripheral modules 120, 125, 130, 135 using the communication channels 120A, 125A, 130A, 135A. Communications between the ADAS hub 115 and the peripheral modules 120, 125, 130, 135 may occur simultaneously. Such multi-directional communications across the same one of the communication channels 120A, 125A, 130A, 135A are referred to as full duplex communications.

In such example operations of the ADAS system 105 of FIG. 1, the ADAS hub 115 receives the serial data streams from the peripheral modules 120, 125, 130, 135. The ADAS hub 115 deserializes the data streams to reconstruct the video streams captured by the peripheral modules 120, 125, 130, 135. The ADAS hub 115 at least one of stores, processes, or displays the video streams for driver assistance. For example, the ADAS hub 115 displays the video stream of the peripheral module 135 on the display 140 responsive to a determination that the perspective corresponding to the peripheral module 135 is needed. In another example, the ADAS hub 115 stores or process video streams of the peripheral modules 120, 125, 130, 135 for detecting safety hazards in the environment of the vehicle 100.

Example operations of the ADAS system 105 are further described in connection with FIG. 2. Advantageously, serializing and deserializing data from the peripheral modules 120, 125, 130, 135 reduces the number of connections within the vehicle 100 to the ADAS hub 115. Advantageously, the serial data streams are capable of accurately traversing relatively large distances across the communication channels 120A, 125A, 130A, 135A.

The IVI system 110 of FIG. 1 includes an example media source 145, example IVI driver circuitry 150, a first example display driver 155, a first example display 160, a second example display 165, a second example display driver 170, and a third example display 175. Alternatively, the IVI system 110 may include any number of display driver(s) or display(s).

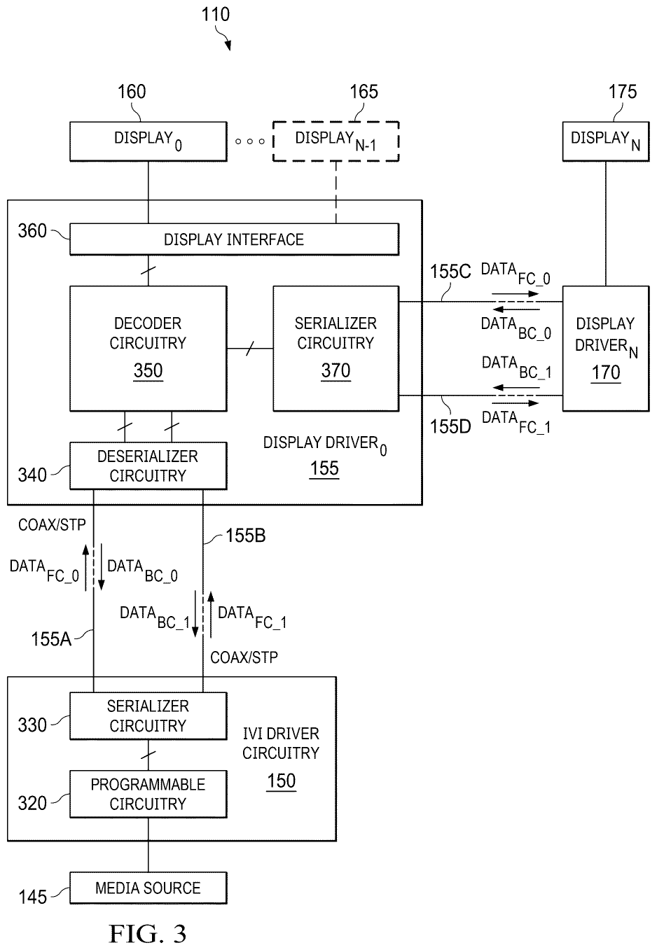

The IVI system 110 is an example type of FPD-link system that utilizes serializing and deserializing media for infotainment on one or more displays (e.g., the displays 160, 165, 175). In some examples, the IVI system 110 is a dashboard having multiple displays for displaying content. In other examples, the IVI system 110 is a different display system having multiple displays for displaying content, such as a studio, workstation, etc. In the example of FIG. 1, the IVI system 110 includes the media source 145, the IVI driver circuitry 150, the display drivers 155, 170, and the displays 160, 165, 175. Alternatively, the IVI system 110 may include any number of media source(s), display driver(s), or display(s). An example of the IVI system 110 is further illustrated and described in connection with FIG. 3.

In the IVI system 110, the media source 145 is coupled to the IVI driver circuitry 150. The media source 145 supplies media to the IVI driver circuitry 150 for display on one or more of the displays 160, 165, 175. In some examples, the media source 145 is integrated in the vehicle 100, such as circuitry supporting a data stream or memory storing media. In other examples, the media source 145 represents a connection to a device that is external to the vehicle 100, such as a wireless connection to a service hosting a multi-media stream.

The IVI driver circuitry 150 is communicatively coupled to the media source 145 and the display driver 155. The IVI driver circuitry 150 processes multi-media data from the media source 145 for transmission to one or more of the display drivers 155, 170. The IVI driver circuitry 150 uses full duplex communications to transmit data to and receive data from the display driver 155. In some examples, the IVI driver circuitry 150 uses LVDS to communicate with the display driver 155. In such examples, the IVI driver circuitry 150 indirectly communicates with the display driver 170 through the display driver 155. Such an example is further illustrated and described in connection with FIG. 3. Alternatively, the IVI driver circuitry 150 may use an alternative type of signaling to communicate with the display driver 155, such as DSI, eDP, etc. An example of the IVI driver circuitry 150 is further illustrated and described in connection with FIG. 3.

The display driver 155 is communicatively coupled to the IVI driver circuitry 150, the displays 160, 165, and the display driver 170. The display driver 155 interfaces with the IVI driver circuitry 150 using first and second communication channels 155A, 155B. The display driver 155 interfaces with the display driver 170 using communication channels 155C, 155D. In the example of FIG. 1, first and second coaxial connectors form the communication channels 155A, 155B between the IVI driver circuitry 150 and the display driver 155. Similarly, third and fourth coaxial connectors form the communication channels 155C, 155D between the display drivers 155, 170. The display driver 155 uses multi-lane signaling to display media on the displays 160, 165. In some examples, the display driver 155 decodes additional data from the IVI driver circuitry 150 to determine which one of the displays 160, 165 corresponds to the data. Although the display driver 155 of FIG. 1 is coupled to the displays 160, 165, the display driver 155 may be coupled to any number of display(s). An example of the display driver 155 is further illustrated and described in connection with FIG. 3.

The display driver 170 is communicatively coupled to the display driver 155 and the display 175. In some examples, the display driver 170 may be coupled to another instance of the display driver 170 (similar to the communication channels 155A, 155B, 155C, 155D of the display driver 155). The display driver 170 interfaces with the display driver 155 using the communication channels 155C, 155D. The display driver 170 uses multi-lane signaling to display multi-media data using the display 175. Although the display driver 155 of FIG. 1 is coupled to the display 175, the display driver 170 may be coupled to any number of display(s).

In an example operation of the IVI system 110 of FIG. 1, the media source 145 supplies media for display on at least one of the displays 160, 165, 175. The IVI driver circuitry 150 determines one or more of the displays 160, 165, 175 to display the media from the media source 145. The IVI driver circuitry 150 determines which of the display drivers 155, 170 are coupled to the one or more of the displays 160, 165, 175. The IVI driver circuitry 150 generates an identifier(s) that specifies at least one of the one or more of the display drivers 155, 170 or one or more of the displays 160, 165, 175. The IVI driver circuitry 150 combines the identifying data and the media from the media source 145. The IVI driver circuitry 150 generates a serial data stream by serializing the combined data for transmission on at least one of the communication channels 155A, 155B.

In such example operations of the IVI system 110, the display driver 155 receives the serial data stream representing the media and identifying data. The display driver 155 deserializes the serial data stream(s) from the communication channels 155A, 155B. The display driver 155 decodes the identifying data to determine if the media corresponds to either of the displays 160, 165. If the display driver 155 determines that the media corresponds to one or more of the displays 160, 165, the display driver 155 displays the media on one or more of the displays 160, 165. If the display driver 155 determines that the media does not correspond to one or more of the displays 160, 165, the display driver 155 regenerates the serial data stream by reserializing the combined media and identifying data. The display driver 155 transmits the serial data to the display driver 170 via at least one of the communication channels 155C, 155D. After receiving the serial data stream from the communication channels 155C, 155D, the display driver 155 deserializes the serial data stream(s). The display driver 170 decodes the identifying data to determine if the media corresponds to the display 175. If the display driver 170 determines that the identifying data corresponds to the display 175, the display driver 170 displays the media on the display 175. In some examples, the display drivers 155, 170 transmit serial data along the communication channels 155A, 155B, 155C, 155D to the IVI driver circuitry 150. In such examples, the concurrent communications from the display drivers 155, 170 may confirm reception or display of the media on one or more of the displays 160, 165, 175.

Example operations of the IVI system 110 are further described in connection with FIG. 3. Serializing and deserializing media from the media source 145 reduces the number of connections to the displays 160, 165, 175 within the vehicle 100. Also, the serial data streams are capable of accurately traversing relatively large distances across the communication channels 155A, 155B, 155C, 155D.

FIG. 2 is a block diagram of an example of the ADAS system 105 of FIG. 1 including the ADAS hub 115, the peripheral modules 120, 135, and the display 140 of FIG. 1. The example ADAS hub 115 of FIG. 2 includes first example power supply circuitry 205, first example deserializer circuitry 210, first example serializer circuitry 215, second example power supply circuitry 220, second example deserializer circuitry 225, second example serializer circuitry 230, example programmable circuitry 235, and example display interface circuitry 240. The example peripheral module 120 of FIG. 2 includes example serializer circuitry 245, example power regulator circuitry 250, and an example sensor 255.

The power supply circuitry 205 has an output coupled to the communication channel 120A and the deserializer circuitry 210. In some examples, the power supply circuitry 205 has an input coupled to a power storage or an electronic control unit (ECU), which supplies power. In other examples, the power supply circuitry 205 is in the peripheral module 120. In such examples, the power supply circuitry 205 directly supplies power to the peripheral module 120. Alternatively, a different method of powering the peripheral module 120 may be used in the circuitry described herein.

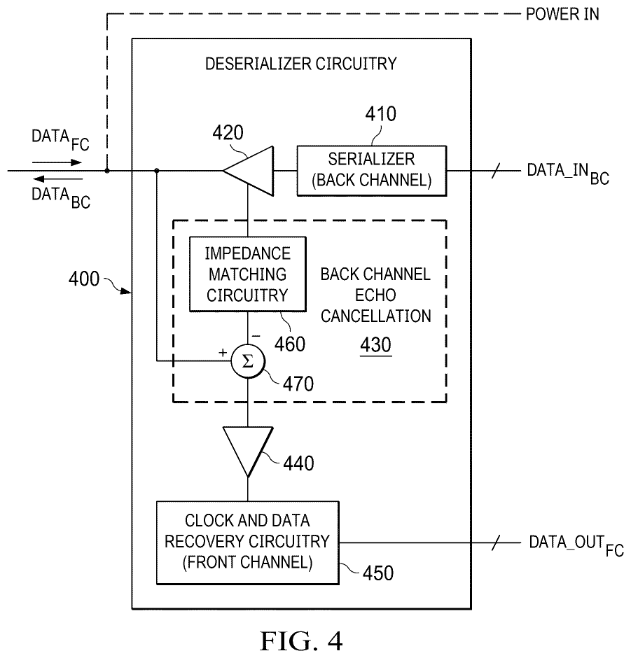

The deserializer circuitry 210 has an input and outputs. The input of the deserializer circuitry 210 is coupled to the communication channel 120A and the power supply circuitry 205. The outputs of the deserializer circuitry 210 are coupled to the serializer circuitry 215 and the programmable circuitry 235. In some examples, the deserializer circuitry 210 communicates with the peripheral module 120 using serial data streams along the communication channel 120A. An example of the deserializer circuitry 210 is further illustrated and described in connection with FIG. 4.

The serializer circuitry 215 has inputs and an output. The inputs of the serializer circuitry 215 are coupled to the deserializer circuitry 210 and the programmable circuitry 235. The output of the serializer circuitry 215 is structured to be coupled to an additional communication channel. In some examples, as illustrated by the dashed lines, the ADAS hub 115 may include the serializer circuitry 215 to connect the ADAS system 105 to external circuitry. In such examples, the serializer circuitry 215 may communicatively couple the ADAS system 105 to another ADAS system, the IVI system 110, storage medium, an ECU, etc. In other examples, the serializer circuitry 215 may be excluded from the ADAS hub 115.

The power supply circuitry 220 has an output coupled to the communication channel 135A and the deserializer circuitry 225. In some examples, the power supply circuitry 220 has an input coupled to a power storage or an ECU, which supplies power. In other examples, the power supply circuitry 220 is in the peripheral module 135. In such examples, the power supply circuitry 220 directly supplies power to the peripheral module 135. Alternatively, a different method of powering the peripheral module 135 may be used in the circuitry described herein.

The deserializer circuitry 225 has an input and outputs. The input of the deserializer circuitry 225 is coupled to the communication channel 135A and the power supply circuitry 220. The outputs of the deserializer circuitry 225 are coupled to the serializer circuitry 230 and the programmable circuitry 235. In some examples, the deserializer circuitry 225 communicates with the peripheral module 135 using serial data streams along the communication channel 135A. An example of the deserializer circuitry 225 is further illustrated and described in connection with FIG. 4.

The serializer circuitry 230 has inputs and an output. The inputs of the serializer circuitry 230 are coupled to the deserializer circuitry 225 and the programmable circuitry 235.

The output of the serializer circuitry 230 is structured to be coupled to an additional communication channel. In some examples, as illustrated by the dashed lines, the ADAS hub 115 may include the serializer circuitry 230 to connect the ADAS system 105 to external circuitry. In such examples, the serializer circuitry 230 may communicatively couple the ADAS system 105 to another ADAS system, the IVI system 110, storage medium, an ECU, etc. In other examples, the serializer circuitry 230 may be excluded from the ADAS hub 115.

The programmable circuitry 235 has first inputs, second inputs, and outputs. The first inputs of the programmable circuitry 235 are coupled to the deserializer circuitry 210 and the serializer circuitry 215. The second inputs of the programmable circuitry 235 are coupled to the deserializer circuitry 225 and the serializer circuitry 230. The outputs of the programmable circuitry 235 are coupled to the display interface circuitry 240. In some examples, the programmable circuitry 235 instantiates circuitry responsive to an execution of machine-readable instructions. In such examples, the programmable circuitry 235 may be one of a central processing unit (CPU), a graphic processing unit (GPU), multi-core processing unit (MCU), etc. Alternatively, the programmable circuitry 235 may be an application specific integrated circuit (ASIC) structured to at least one of store, process, or condition data from the deserializer circuitry 210, 225.

The display interface circuitry 240 has inputs and outputs. The inputs of the display interface circuitry 240 are coupled to the programmable circuitry 235. The outputs of the display interface circuitry 240 are coupled to the display 140. In some examples, the display interface circuitry 240 represents a display driver, which converts data from the programmable circuitry 235 to drive the display 140. In some such examples, the display interface circuitry 240 may include a port and connector specific for driving the display 140, such as a display port, a high-definition multimedia interface (HDMI) port, etc.

The serializer circuitry 245 has inputs and an output. The inputs of the serializer circuitry 245 are coupled to the sensor 255. The output of the serializer circuitry 245 is coupled to the communication channel 120A and the power regulator circuitry 250. In some examples, the serializer circuitry 245 communicates with the ADAS hub 115 using serial data streams along the communication channel 120A. An example of the serializer circuitry 245 is further illustrated and described in connection with FIG. 4.

In the example of FIG. 2, the deserializer circuitry 210 is communicatively coupled to the serializer circuitry 245 by a full duplex wireline connection represented by the communication channel 120A. In some examples, both the deserializer circuitry 210 and the serializer circuitry 245 may receive data from or transmit data on the communication channel 120A. In such examples, the input of the deserializer circuitry 210 and the output of the serializer circuitry 245 are bi-directional. Such an example is further described in connection with FIG. 4.

The power regulator circuitry 250 has an input and an output. The input of the power regulator circuitry 250 is coupled to the communication channel 120A and the serializer circuitry 245. The output of the power regulator circuitry 250 is coupled to the sensor 255. The power regulator circuitry 250 receives power from the power supply circuitry 205. In some examples, such as in FIG. 2, the power regulator circuitry 250 receives power through the communication channel 120A. In other examples, the power supply circuitry 205 may be coupled to the power regulator circuitry 250 by a separate connection or positioned in proximity to the peripheral module 120.

The sensor 255 has an input and outputs. The input of sensor 255 is coupled to the power regulator circuitry 250. The outputs of the sensor 255 are coupled to the serializer circuitry 245. In some examples, the sensor 255 produces data corresponding to a surrounding environment. For example, in FIG. 1, the sensor 255 may be a camera positioned to capture a portion of the environment surrounding the vehicle 100. In another example, the sensor 255 may be an alternative type of sensor for corresponding to characteristics of the surrounding environment of the vehicle 100, such as obstacles.

In example operation, the power supply circuitry 205 supplies power to the power regulator circuitry 250 through the communication channel 120A. In some examples, such as the communication channel 120A being a coaxial connector, the power supply circuitry 205 and the power regulator circuitry 250 implement power over coax (POC). In such examples, the power supply circuitry 205 supplies power (POWER IN) and the power regulator circuitry 250 receives power (POWER OUT). The power regulator circuitry 250 powers the sensor 255, or more generally the peripheral module 120 based on power from the power supply circuitry 205. Similarly, the power supply circuitry 220 may utilize the communication channel 135A to supply power to the peripheral module 135.

The sensor 255 generates data corresponding to the surrounding environment. In some examples, the sensor 255 is a camera that produces multimedia data corresponding to a perspective of the surrounding environment. In another example, the sensor 255 is a lidar device that produces time of flight data corresponding to potential obstacles in the surrounding environment. In yet another example, the sensor 255 is a radar that produces beamforming data corresponding to the surrounding environment. Alternatively, the sensor 255 may be an alternative type of sensor that produces an alternative type of data. In such example operations, the sensor 255 produces sensor data using multiple parallel data paths (also referred to as lines or lanes). The serializer circuitry 245 serializes data of the multiple parallel data paths to produce a serial data stream having a data rate greater than the data rate of the parallel data paths from the sensor 255. The serializer circuitry 245 transmits the serial data stream to the deserializer circuitry 210 using a front channel of the communication channel 120A. Such data of the serial data stream is referred to as front channel data (DATA_{FC_0}).

In example operation, the deserializer circuitry 210 receives the serial data stream after traversing the communication channel 120A. Concurrently, the deserializer circuitry 210 may transmit a serial data stream to the serializer circuitry 245 using a back-channel of the communication channel 120A. Such data is referred to as back-channel data (DATA_{BC_0}). In such examples, the front channel data has a data rate greater than the back-channel data to reduce interference. Such multi-directional communications along the communication channel 120A are referred to as full-duplex communications. The deserializer circuitry 210 may use the back-channel of the communication channel 120A to control settings of the sensor 255 or verify reception of data on the front channel. Similarly, the peripheral module 135 and the deserializer circuitry 225 may utilize full-duplex communications along the communication channel 135A to exchange front and back-channel data (DATA_{FC_N}, DATA_{BC_N}).

In example operation, the deserializer circuitry 210 deserializes the front channel data to produce multiple parallel data paths. In some examples, the deserializer circuitry 210 may decode identifying data from the front channel data. In such examples, the serializer circuitry 215 may serialize and transmit the front channel data to external circuitry responsive to the deserializer circuitry 210 decoding identifying data corresponding to external circuitry. Advantageously, the serializer circuitry 215 allows the ADAS system 105 to be coupled to another instance of the ADAS system 105, the IVI system 110, or alternative type of data processing system.

In example operation, the programmable circuitry 235 at least one of processes, stores, or conditions the data of the multiple parallel data paths for the display 140. In some examples, the programmable circuitry 235 combines data from the peripheral modules 120, 135 prior to display. For example, the programmable circuitry 235 may stitch video streams from the peripheral modules 120, 135 to display a larger portion of the surrounding environment. In such examples, the display interface circuitry 240 structures the data from the programmable circuitry 235 to drive the display 140. In some examples, the display interface circuitry 240 is at least one of a column pixel driver or a row pixel driver. The display 140 produces a perceivable representation of the data from at least one of the peripheral modules 120, 135.

Example operations of the serializer and deserializer system of the ADAS system 105 are further described in connection with FIGS. 4, 5, and 6. Advantageously, serializing and deserializing data from the peripheral modules 120, 135 reduces the number of connections to the ADAS hub 115. Advantageously, the serial data streams are capable of accurately traversing relatively large distances across the communication channels 120A, 135A.

FIG. 3 is a block diagram of an example of the IVI system 110 of FIG. 1. The IVI system 110 of FIG. 3 includes the media source 145, the IVI driver circuitry 150, the example of the display driver 155, 170, and the displays 160, 165, 175 of FIG. 1. The example IVI driver circuitry 150 of FIG. 3 includes example programmable circuitry 320 and example serializer circuitry 330. The example display driver 155 of FIG. 3 includes example deserializer circuitry 340, example decoder circuitry 350, example display interface circuitry 360, and example serializer circuitry 370.

The programmable circuitry 320 has an input and outputs. The input of the programmable circuitry 320 is coupled to the media source 145. The outputs of the programmable circuitry 320 are coupled to the serializer circuitry 330. In some examples, the programmable circuitry 320 instantiates circuitry responsive to the execution of machine-readable instructions. In such examples, the programmable circuitry 320 may be one of a CPU, a GPU, an MCU, etc. Alternatively, the programmable circuitry 235 may be an ASIC structured to at least one of store, process, or condition data from the media source 145.

The serializer circuitry 330 has inputs, a first output, and a second output. The inputs of the serializer circuitry 330 are coupled to the programmable circuitry 320. The first output of the serializer circuitry 330 is coupled to the communication channel 155A. The second output of the serializer circuitry 330 is coupled to the communication channel 155B. In some examples, the serializer circuitry 330 communicates with the display driver 155 using serial data streams along the communication channels 155A, 155B. An example of the serializer circuitry 330 is further illustrated and described in connection with FIG. 4. Unlike the serializer circuitry 245 of FIG. 2, the serializer circuitry 330 exchanges data using multiple serial data streams along the communication channels 155A, 155B. In some examples, the serializer circuitry 330 may be illustrated and described as a plurality of instances of the serializer circuitry 330 supporting a single one of the communication channels 155A, 155B. For example, the serializer circuitry 330 may be separated into two instances of the serializer circuitry 330.

The deserializer circuitry 340 has a first input, a second input, and outputs. The first input of the deserializer circuitry 340 is coupled to the communication channel 155A. The second input of the deserializer circuitry 340 is coupled to the communication channel 155B. The outputs of the deserializer circuitry 340 are coupled to the decoder circuitry 350. In some examples, the deserializer circuitry 340 communicates with the IVI driver circuitry 150 using serial data streams along the communication channels 155A, 155B. An example of the deserializer circuitry 340 is further illustrated and described in connection with FIG. 4. Unlike the deserializer circuitry 210, 225 of FIG. 2, the deserializer circuitry 340 exchanges data using multiple serial data streams along the communication channels 155A, 155B. In some examples, the deserializer circuitry 340 may be illustrated and described as a plurality of instances of the deserializer circuitry 340 supporting a single one of the communication channels 155A, 155B. For example, the deserializer circuitry 340 may be separated into two instances of the deserializer circuitry 340, such as the deserializer circuitry 210, 225 of FIG. 2.

The decoder circuitry 350 has inputs, first outputs, and second outputs. The inputs of the decoder circuitry 350 are coupled to the deserializer circuitry 340. The first outputs of the decoder circuitry 350 are coupled to the display interface 360. The second outputs of the decoder circuitry 350 are coupled to the serializer circuitry 370. In some examples, the decoder circuitry 350 is implemented using programmable circuitry or an ASIC. In such examples, the decoder circuitry 350 is structured to route data from the deserializer circuitry 340 to at least one of the display interface 360 or the serializer circuitry 370 responsive to the decoded portions of the data. Such portions of the data from the deserializer circuitry 340 may be referred to as identifying data, which specifies one or more of the displays 160, 165, 175 to display the media on.

The display interface 360 has inputs, first outputs, and second outputs. The inputs of the display interface 360 are coupled to the decoder circuitry 350. The first outputs of the display interface 360 are coupled to the display 160. The second outputs of the display interface 360 are coupled to the display 165. In some examples, the display interface 360 drives one or more of the displays 160, 165 responsive to data from the decoder circuitry 350. In some such examples, the display interface 360 may include a port and connector specific for driving the displays, such as a display port, an HDMI port, etc. In the example of FIG. 3, the display interface 360 drives the displays 160, 165. Alternatively, the display driver 155 may include any number of display interfaces 360 for driving any number of displays, such as the displays 160, 165.

The serializer circuitry 370 has inputs, a first output, and a second output. The inputs of the serializer circuitry 370 are coupled to the decoder circuitry 350. The first output of the serializer circuitry 370 is coupled to the communication channel 155C. The second output of the serializer circuitry 370 is coupled to the communication channel 155D. In some examples, the serializer circuitry 370 communicates with the display driver 170 using serial data streams along the communication channels 155C, 155D. An example of the serializer circuitry 370 is further illustrated and described in connection with FIG. 4. Similar to the serializer circuitry 330, the serializer circuitry 370 exchanges data using multiple serial data streams along the communication channels 155C, 155D. In some examples, the serializer circuitry 370 may be illustrated and described as a plurality of instances of the serializer circuitry 370 supporting one of the communication channels 155C, 155D. For example, the serializer circuitry 370 may be separated into two instances of the serializer circuitry 370.

In example operations, the programmable circuitry 320 receives multimedia data from the media source 145. In some examples, the media source 145 is internal to the IVI system 110, such as memory storage, an ECU, a media stream, etc. In other examples, the media source 145 is external to the IVI system 110, such as a wireless connection to a service hosting a multi-media stream. The programmable circuitry 320 identifies one or more of the displays 160, 165, 175 that correspond to the data from the media source 145. In some examples, the programmable circuitry 320 encodes additional data onto the data from the media source 145 corresponding to different operations of the IVI system 110. For example, the programmable circuitry 320 adds identifying data into portions of the data from the media source 145 to specify one or more of the displays 160, 165, 175 that correspond to the media. In such examples, the identifying data may specify the one or more of the displays 160, 165, 175. The programmable circuitry 320 supplies the data to the serializer circuitry 330 for transmission to the display drivers 155, 170.

In example operations, the serializer circuitry 330 receives data from the programmable circuitry 320 on multiple parallel data paths. The serializer circuitry 330 serializes data of the multiple parallel data paths to produce a first and second serial data stream having a data rate greater than the data rate of the parallel data paths from the programmable circuitry 320. The serializer circuitry 330 transmits the first serial data stream to the deserializer circuitry 340 using a front channel of the communication channel 155A. The data of the first serial data stream is referred to as first front channel data (DATA_{FC_0}). The serializer circuitry 330 transmits the second serial data stream to the deserializer circuitry 340 using a front channel of the communication channel 155B. The data of the second serial data stream is referred to as second front channel data (DATA_{FC_1}). Advantageously, increasing the number of communication channels between the serializer circuitry 330 and the deserializer circuitry 340 increases the possible number of displays the IVI system 110 may support at a given time.

In example operation, the deserializer circuitry 340 receives the first and second serial data streams after traversing the communication channels 155A, 155B. Concurrently, the deserializer circuitry 340 may transmit a first serial data stream to the serializer circuitry 330 using a back-channel of the communication channel 155A. The data of the first serial data stream is referred to as first back-channel data (DATA_{BC_0}). Similarly, the deserializer circuitry 340 may transmit a second serial data stream to the serializer circuitry 330 using a back-channel of the communication channel 155B. The data of the second serial data stream is referred to as second back-channel data (DATA_{BC_1}). In such examples, the first and second front channel data has a data rate may be greater than the first and second back-channel data to reduce interference. Such multi-directional communications along the communication channels 155A, 155B are referred to as full-duplex communications. The deserializer circuitry 340 may use the back-channel of the communication channels 155A, 155B to verify reception of the first and second front channel data, report errors to the programmable circuitry 320, etc. Similarly, the display driver 170 and the serializer circuitry 370 may utilize full-duplex communications along the communication channels 155C, 155D to exchange third and fourth front channel data (DATA_{FC_2}, DATA_{FC_3}) and third and fourth back-channel data (DATA_{BC_2}, DATA_{BC_3}).

In example operations, the deserializer circuitry 340 deserializes the first and second front channel data to produce multiple parallel data paths. The decoder circuitry 350 decodes the data from the media source 145 from the additional data from the programmable circuitry 320. The decoder circuitry 350 determines which one or more of the displays 160, 165, 175 correspond to the data from the media source 145 responsive to the decoded data. In some examples, the decoder circuitry 350 supplies the multiple parallel data paths to the serializer circuitry 370 responsive to a determination that the media does not correspond to the displays 160, 165. In such examples, the serializer circuitry 370 serializes and transmits the third and fourth front channel data to the display driver 170. Advantageously, the display driver 170 may be coupled in series with another instance of the display driver 170 by additional communication channels, such as a fifth and sixth communication channel.

In example operation, the decoder circuitry supplies the multiple parallel data paths to the display interface 360 responsive to a determination that the media from the media source 145 corresponds to at least one of the displays 160, 165. In some examples, the display interface 360 structures the data from the decoder circuitry 350 to drive one or more of the displays 160, 165. In some examples, the display interface 360 is at least one of a column pixel driver or a row pixel driver. In such examples, at least one of the displays 160, 165 produce a perceivable representation of the media from the media source 145 responsive to the display interface 360.

Example operations of the serializer and deserializer system of the IVI system 110 are further described in connection with FIGS. 4, 5, and 6. Advantageously, serializing and deserializing data from the media source 145 reduces the number of connections to one or more of the displays 160, 165, 175. Also, the serial data streams are capable of accurately traversing relatively large distances across the communication channels 155A, 155B, 155C, 155D.

FIG. 4 is a block diagram of example deserializer circuitry 400, which is an example of the deserializer circuitry 210, 225, 340 of FIGS. 2 and 3. The example deserializer circuitry 400 of FIG. 4 includes an example serializer 410, example back-channel transmitter circuitry 420, example back-channel echo cancellation circuitry 430, example receiver circuitry 440, and example clock and data recovery (CDR) circuitry 450. The example echo cancelation circuitry 430 includes example impedance matching circuitry 460 and example combination circuitry 470.

The deserializer circuitry 400 is structured to be coupled to the serializer circuitry 245, 330 of FIGS. 2 and 3 by at least one of the communication channels 120A, 135A, 155A, 155B. The deserializer circuitry 400 has inputs (DATA_IN_{BC}) and outputs (DATA_OUT_{FC}). The inputs and outputs of the deserializer circuitry 400 are structured to be coupled to one of the programmable circuitry 235 of FIG. 2 or the decoder circuitry 350 of FIG. 3. The inputs of the deserializer circuitry 400 receive back-channel data for transmission along at least one of the communication channels 120A, 135A, 155A, 155B. The outputs of the deserializer circuitry 400 provide front channel data from the at least one of the communication channels 120A, 135A, 155A, 155B.

The serializer 410 has inputs and an output. The inputs of the serializer 410 are coupled to the inputs of the deserializer circuitry 400 (DATA_IN_{BC}). The output of the serializer 410 is coupled to the transmitter circuitry 420. In some examples, the serializer 410 is referred to as a back-channel serializer.

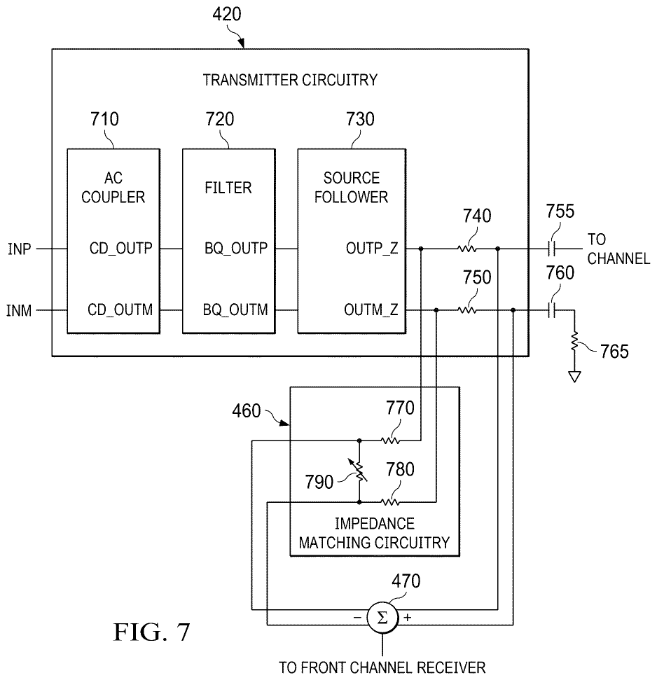

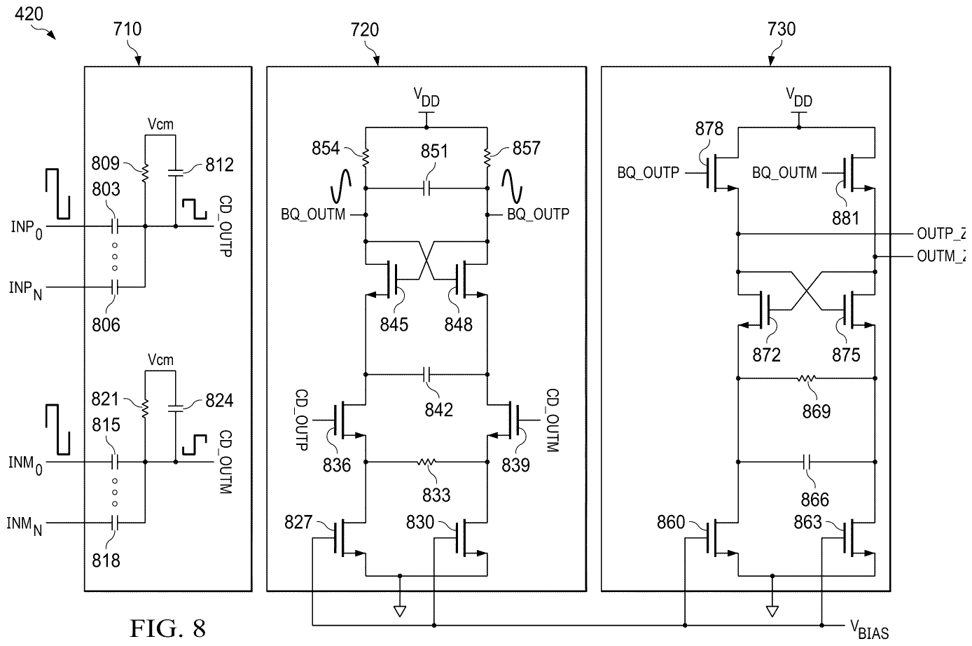

The transmitter circuitry 420 has an input, a first output, and a second output. The input of the transmitter circuitry 420 is coupled to the serializer 410. The first output of the transmitter circuitry 420 is coupled to the echo cancellation circuitry 430 and at least one of the communication channels 120A, 135A, 155A, 155B. The second output of the transmitter circuitry 420 is coupled to the echo cancellation circuitry 430. In some examples, the transmitter circuitry 420 is referred to as a back-channel transmitter. Examples of the transmitter circuitry 420 are further illustrated and described in connection with FIGS. 7 and 8.

The echo cancelation circuitry 430 has a first input, a second input, and an output. The first input of the echo cancelation circuitry 430 is coupled to the transmitter circuitry 420. The second input of the echo cancelation circuitry 430 is coupled to the transmitter circuitry 420 and at least one of the communication channels 120A, 135A, 155A, 155B. The output of the echo cancelation circuitry 430 is coupled to the receiver circuitry 425. In some examples, the echo cancelation circuitry 430 is referred to as back-channel echo cancelation circuitry. An example of the echo cancelation circuitry 430 is further illustrated and described in connection with FIG. 7.

The receiver circuitry 440 has an input and an output. The input of the receiver circuitry 440 is coupled to the echo cancelation circuitry 430. The output of the receiver circuitry 440 is coupled to the CDR circuitry 450. In some examples, the receiver circuitry 440 is referred to as a front channel receiver.

The CDR circuitry 450 has an input and outputs. The input of the CDR circuitry 450 is coupled to the receiver circuitry 440. The outputs of the CDR circuitry 450 are coupled to the outputs of the deserializer circuitry 400 (DATA_OUT_{FC}). In some examples, the CDR circuitry 450 is referred to as front channel CDR circuitry.

The impedance matching circuitry 460 (also referred to as load circuitry) has an input and an output. The input of the load circuitry 460 is coupled to the transmitter circuitry 420. The output of the load circuitry 460 is coupled to the combination circuitry 470. An example of the load circuitry 460 is further illustrated and described in connection with FIG. 7.

The combination circuitry 470 has a first input, a second input, and an output. The first input of the combination circuitry 470 is coupled to the transmitter circuitry 420 and at least one of the communication channels 120A, 135A, 155A, 155B. The second input of the combination circuitry 470 is coupled to the transmitter circuitry 420. The output of the combination circuitry 470 is coupled to the receiver circuitry 440.

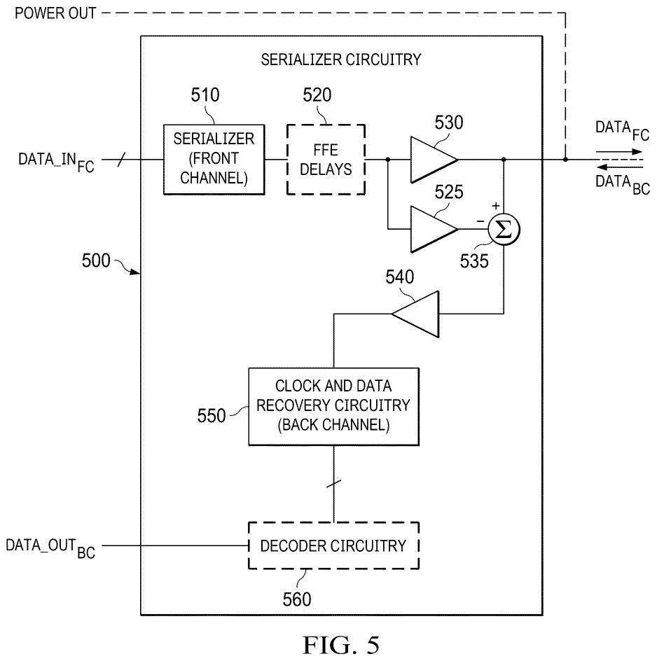

FIG. 5 is a block diagram of example serializer circuitry 500, which is an example of the serializer circuitry 245, 330 of FIGS. 2 and 3. The example serializer circuitry 500 of FIG. 5 includes an example serializer 510, example delay circuitry 520, first example transmitter circuitry 525, second example transmitter circuitry 530, example combination circuitry 535, example receiver circuitry 540, example CDR circuitry 550, and example decoder circuitry 560.

The serializer circuitry 500 is structured to be coupled to the deserializer circuitry 210, 225, 340, 400 of FIGS. 2, 3, and 4 by at least one of the communication channels 120A, 135A, 155A, 155B, 155C, 155D of FIGS. 1, 2, and 3. The serializer circuitry 500 has inputs (DATA_IN_{FC}) and outputs (DATA_OUT_{BC}). The inputs and outputs of the serializer circuitry 500 are structured to be coupled to one of the sensor 255 of FIG. 2 or the programmable circuitry 320 of FIG. 3. The inputs of the serializer circuitry 500 receive front channel data for transmission along at least one of the communication channels 120A, 135A, 155A, 155B, 155C, 155D. The outputs of the serializer circuitry 500 provide back-channel data from at least one of the communication channels 120A, 135A, 155A, 155B, 155C, 155D.

The serializer 510 has inputs and an output. The inputs of the serializer 510 are coupled to the inputs of the serializer circuitry 500 (DATA_IN_{FC}). The output of the serializer 510 is coupled to the delay circuitry 520. In some examples, the serializer circuitry 500 is referred to as a front-channel serializer.

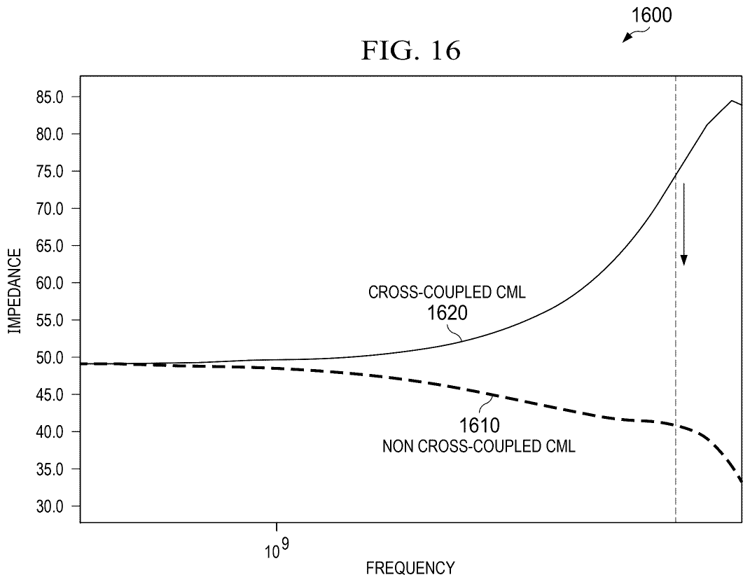

The delay circuitry 520 has an input and an output. The input of the delay circuitry 520 is coupled to the serializer 510. The output of the delay circuitry 520 is coupled to the transmitter circuitry 525, 530. An example of the delay circuitry 520 is further illustrated and described in connection with FIG. 16.

The transmitter circuitry 525 has an input and an output. The input of the transmitter circuitry 525 is coupled to the delay circuitry 520 and the transmitter circuitry 530. The output of the transmitter circuitry 525 is coupled to the combination circuitry 535. In some examples, the transmitter circuitry 525 is referred to as a secondary transmitter or a replica transmitter.

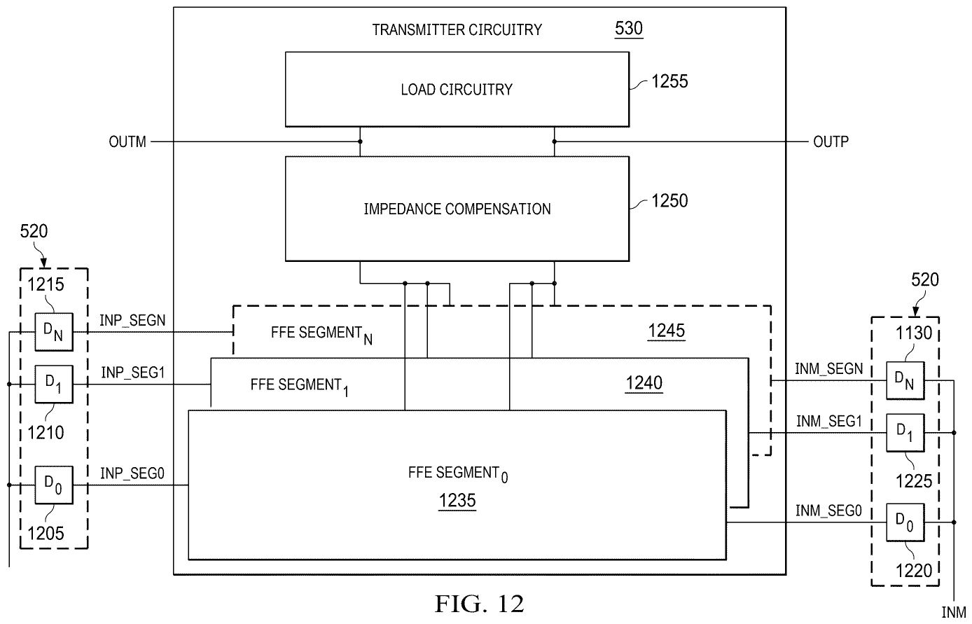

The transmitter circuitry 530 has an input and an output. The input of the transmitter circuitry 530 is coupled to the delay circuitry 520. In some examples, as illustrated by the dashed lines, the input of the transmitter circuitry 525, 530 are directly coupled to the output of the serializer 510. The output of the transmitter circuitry 530 is coupled to the combination circuitry 535 and at least one of the communication channels 120A, 135A, 155A, 155B, 155C, 155D. In some examples, the transmitter circuitry 530 is referred to as a front-channel transmitter or a primary transmitter. Examples of the transmitter circuitry 530 are further illustrated and described in connection with FIGS. 12, 13, and 14.

The combination circuitry 535 has a first input, a second input, and an output. The first input of the combination circuitry 535 is coupled to the transmitter circuitry 525. The second input of the combination circuitry 535 is coupled to the transmitter circuitry 530 and at least one of the communication channels 120A, 135A, 155A, 155B, 155C, 155D. The output of the combination circuitry 535 is coupled to the receiver circuitry 540. In some examples, the transmitter circuitry 525 and the combination circuitry 535 are illustrated or referred to as echo cancellation circuitry. In the example of FIG. 5, the combination circuitry 535 is subtraction circuitry. Alternatively, in other examples, the combination circuitry 535 is alternative circuitry.

The receiver circuitry 540 has an input and an output. The input of the receiver circuitry 540 is coupled to the combination circuitry 535. The output of the receiver circuitry 540 is coupled to the CDR circuitry 550. In some examples, the receiver circuitry 540 is referred to as a back-channel receiver.

The CDR circuitry 550 has an input and outputs. The input of the CDR circuitry 550 is coupled to the receiver circuitry 540. The outputs of the CDR circuitry 550 are coupled to the decoder circuitry 560. In some examples, the CDR circuitry 550 is referred to as back-channel CDR circuitry.

The decoder circuitry 560 has inputs and outputs. The inputs of the decoder circuitry 560 are coupled to the CDR circuitry 550. The outputs of the decoder circuitry 560 are coupled to the outputs of the serializer circuitry 500 (DATA_OUT_{BC}). In some examples, as illustrated by the dashed lines, the outputs of the CDR circuitry 550 are directly coupled to the outputs of the serializer circuitry 500 (DATA_OUT_{BC}).

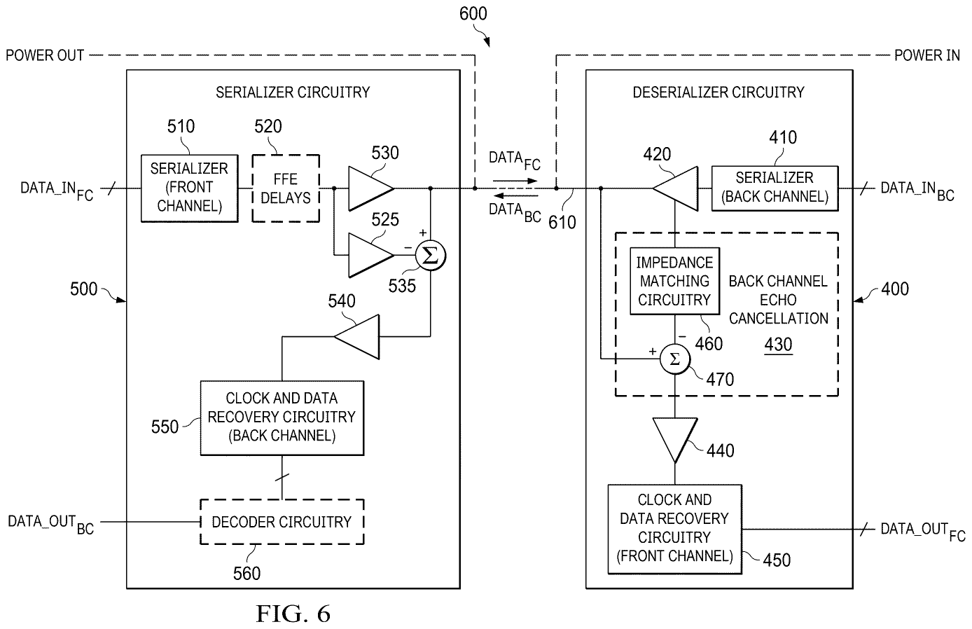

FIG. 6 is a block diagram of an example serial-deserializer (SerDes) system 600, which is a full-duplex communication system, including the deserializer circuitry 400 of FIG. 4 and the serializer circuitry 500 of FIG. 5. The example deserializer circuitry 400 of FIG. 6 includes the serializer 410 of FIG. 4, the transmitter circuitry 420 of FIG. 4, the echo cancelation circuitry 430 of FIG. 4, the receiver circuitry 440 of FIG. 4, and the CDR circuitry 450 of FIG. 4. The example serializer circuitry 500 of FIG. 6 includes the serializer 510 of FIG. 5, the delay circuitry 520 of FIG. 5, the transmitter circuitry 525, 530 of FIG. 5, the combination circuitry 535 of FIG. 5, the receiver circuitry 540 of FIG. 5, the CDR circuitry 550 of FIG. 5, and the decoder circuitry 560 of FIG. 5.

The SerDes system 600 includes an example communication channel 610 coupled between the deserializer circuitry 400 and the serializer circuitry 500. In some examples, the communication channel 610 is a coaxal connector. In other examples, the communication channel 610 is a standard wire pair or alternative connection. In the example of the ADAS system 105 of FIG. 2, the deserializer circuitry 400 represents the deserializer circuitry 210 in the ADAS hub 115 and the serializer circuitry 500 represents the serializer circuitry 245 in the peripheral module 120. In the example of the IVI system 110 of FIG. 3, the deserializer circuitry 400 represents the deserializer circuitry 340 in the display driver 155. Also, in the example of the IVI system 110 of FIG. 3, the serializer circuitry 500 represents the serializer circuitry 330 in the IVI driver circuitry 150 or the serializer circuitry 370 in the display driver 155.

In example operations, the deserializer circuitry 400 receives back-channel data (DATA_{BC}) via multiple data paths from an external data source, such as the programmable circuitry 235 or the decoder circuitry 350. The serializer 410 produces a back-channel serial data stream responsive to the back-channel data. The transmitter circuitry 420 transmits the back-channel data to the serializer circuitry 500 across the communication channel 610. Similarly, the serializer circuitry 500 receives front channel data (DATA_{FC}) via multiple data paths from an external data source, such as the sensor 255 or the programmable circuitry 320. The serializer 510 produces a front channel serial data stream responsive to the front channel data. In some examples, the serializer circuitry 500 includes the delay circuitry 520, which supports feed-forward equalization (FFE). In such examples, the delays of the delay circuitry 520 modulate the amplitudes of digital pulses to reduce attenuation along the communication channel 610. The transmitter circuitry 530 transmits the front channel data to the deserializer circuitry 400 across the communication channel 610. Also, the transmitter circuitry 525 provides a replica of the front channel data to the combination circuitry 535.

In some examples, as further described below, the transmitter circuitry 420, 530 may include circuitry to impedance match the communication channel 610 to reduce reflections. Also, the transmitter circuitry 420, 530 may have different bandwidths. In such examples, the data rates of the transmissions of the front and back-channel data are different to prevent interference. In some examples, the bandwidth of the transmitter circuitry 420, which transmits the back-channel data, is modified to reduce non-linear gain contributions of the communication channel 610. Advantageously, the serializers 410, 510 and the transmitter circuitry 420, 530 support full-duplex data transmissions along the communication channel 610.

In example operations, the deserializer circuitry 400 receives the front channel data (DATA_{FC}) after propagating along the communication channel 610. The receiver circuitry 440 produces a serial data stream representing the front channel data responsive to signals from the communication channel 610. In some examples, the receiver circuitry 440 isolates the communication channel 610 from the CDR circuitry 450. The echo cancelation circuitry 430 reduces contributions of the back-channel data from signals received by the transmitter circuitry 420.

Similarly, the serializer circuitry 500 receives the back-channel data (DATA_{BC}) after propagating along the communication channel 610. The combination circuitry 535 subtracts the replica front channel data from signals of the communication channel 610. The combination circuitry 535 provides a communication signal representing the back-channel data to the receiver circuitry 540. The receiver circuitry 540 produces a serial data stream representing the back-channel data responsive to signals from the communication channel 610. In some examples, the receiver circuitry 540 isolates the communication channel 610 from the CDR circuitry 550. Also, the receiver circuitry 440, 540 terminate currents of the communication channel 610.

In example operations, the CDR circuitry 450 receives the front channel data from the receiver circuitry 440. The CDR circuitry 450 retimes the font channel data to produce multiple parallel data paths representing the front channel data. The outputs of the deserializer circuitry 400 provide the front channel data to external circuitry, such as the programmable circuitry 235 or the decoder circuitry 350. Similarly, the CDR circuitry 550 receives the back-channel data from the receiver circuitry 455. The CDR circuitry 550 produces multiple parallel data paths representing the back-channel data. In some such example operations, the decoder circuitry 560 decodes portions of the back-channel data prior to the outputs of the serializer circuitry 500 supplying the back-channel data to external circuitry, such as the sensor 255 or the programmable circuitry 320.

Example operations of the transmitter circuitry 420 and the echo cancelation circuitry 430 are further illustrated and described in connection with FIGS. 7, 8, and 9. Example operations of the delay circuitry 520 and the transmitter circuitry 530 are further illustrated and described in connection with FIGS. 12, 13, 14, and 15. Advantageously, serializing and deserializing front and back-channel data reduces the number of connections that need to traverse relatively large distances of the communication channel 610. Advantageously, the serial data streams are capable of accurately traversing relatively large distances across the communication channels 610.

FIG. 7 is a block diagram of an example of the transmitter circuitry 420 of FIGS. 4 and 6, the load circuitry 460 of FIGS. 4 and 6, and the combination circuitry 470 of FIGS. 4 and 6. The example transmitter circuitry 420 of FIG. 7 includes example AC coupler circuitry 710, example filter circuitry 720, example source follower circuitry 730, a first example resistor 740, and a second example resistor 750. In the example of FIG. 7, the transmitter circuitry 420 is structured to be coupled to the communication channel 610 of FIG. 6 by an example capacitor 755. Similarly, the differential output of the transmitter circuitry 420 is terminated by an example capacitor 760 and an example resistor 765. The example load circuitry 460 of FIG. 7 includes a first example resistor 770, a second example resistor 780, and a third example resistor 790.

The transmitter circuitry 420 has a first input, a second input, a first output, a second output, a third output, and a fourth output. The first and second inputs of the transmitter circuitry 420 (INP, INM) are structured to be coupled to a digital signal source. The digital signal source provides a differential pair of digital signals at the first and second inputs of the transmitter circuitry 420. For example, the serializer 410 of FIG. 4 provides a serial data stream for transmission across the communication channel 610 of FIG. 6. The first and second outputs of the transmitter circuitry 420 are coupled to the load circuitry 460. The third output of the transmitter circuitry 420 is coupled to the combination circuitry 470 and the capacitor 755. The fourth output of the transmitter circuitry 420 is coupled to the combination circuitry 470 and the capacitor 760. In some examples, the transmitter circuitry 420 is referred to as back-channel transmitter circuitry.

The load circuitry 460 has a first input, a second input, a first output, and a second output. The first and second inputs of the load circuitry 460 are coupled to the transmitter circuitry 420. The first and second outputs of the load circuitry 460 are coupled to the combination circuitry 470.

The combination circuitry 470 has a first input, a second input, a third input, a fourth input, and an output. The first and second inputs of the combination circuitry 470 are coupled to the transmitter circuitry 420 and the capacitors 755, 760. The third and fourth inputs of the combination circuitry 470 are coupled to the load circuitry 460. The output of the combination circuitry 470 is structured to be coupled to receiver circuitry, such as the receiver circuitry 440 of FIG. 4.

The AC coupler circuitry 710 has a first input, a second input, a first output, and a second output. The first and second inputs of the AC coupler circuitry 710 are coupled to the first and second inputs of the transmitter circuitry 420 (INP, INM). The first and second outputs of the AC coupler circuitry 710 (CD_OUTP, CD_OUTM) are coupled to the filter circuitry 720. An example of the AC coupler circuitry 710 is further illustrated and described in connection with FIG. 8.

The filter circuitry 720 has a first input, a second input, a first output, and a second output. The first and second inputs of the filter circuitry 720 are coupled to the AC coupler circuitry 710. The first and second outputs of the filter circuitry 720 (BQ_OUTP, BQ_OUTM) are coupled to the source follower circuitry 730. An example of the filter circuitry 720 is further illustrated and described in connection with FIG. 8.

The source follower circuitry 730 has a first input, a second input, a first output, and a second output. The first and second inputs of the source follower circuitry 730 are coupled to the filter circuitry 720. The first output of the source follower circuitry 730 (OUTP_Z) is coupled to the resistors 740, 770. The second output of the source follower circuitry 730 (OUTM_Z) is coupled to the resistors 750, 780. An example of the source follower circuitry 730 is further illustrated and described in connection with FIG. 8.

The resistor 740 has a first terminal and a second terminal. The first terminal of the resistor 740 is coupled to the source follower circuitry 730 and the resistor 770. The second terminal of the resistor 740 is coupled to the combination circuitry 470 and the capacitor 755. In some examples, the resistor 740 has a trim input. In such examples, trim circuitry provides a trim value to the resistor 740. The trim value sets the resistance of the resistor 740. Such resistors are referred to as trimmable resistors.

The resistor 750 has a first terminal and a second terminal. The first terminal of the resistor 750 is coupled to the source follower circuitry 730 and the resistor 780. The second terminal of the resistor 750 is coupled to the combination circuitry 470 and the capacitor 760. In some examples, the resistor 750 has a trim input. In such examples, trim circuitry provides a trim value to the resistor 750. The trim value sets the resistance of the resistor 750. Such resistors are referred to as trimmable resistors.

The capacitor 755 has a first terminal and a second terminal. The first terminal of the capacitor 755 is coupled to the combination circuitry 470 and the resistor 740. The second terminal of the capacitor 755 is structured to be coupled to a communication channel, such as the communication channel 610.

The capacitor 760 has a first terminal and a second terminal. The first terminal of the capacitor 760 is coupled to the combination circuitry 470 and the resistor 750. The second terminal of the capacitor 760 is coupled to the resistor 765.

The resistor 765 has a first terminal and a second terminal. The first terminal of the resistor 765 is coupled to the capacitor 760. The second terminal of the resistor 765 is coupled to a common terminal, which provides a common potential (e.g., ground, AVSS, etc.).

The resistor 770 has a first terminal and a second terminal. The first terminal of the resistor 770 is coupled to the source follower circuitry 730 and the resistor 740. The second terminal of the resistor 770 is coupled to the combination circuitry 470 and the resistor 790.

The resistor 780 has a first terminal and a second terminal. The first terminal of the resistor 780 is coupled to the source follower circuitry 730 and the resistor 750. The second terminal of the resistor 780 is coupled to the combination circuitry 470 and the resistor 790.

The resistor 790 has a first terminal and a second terminal. The first terminal of the resistor 790 is coupled to the combination circuitry 470 and the resistor 770. The second terminal of the resistor 790 is coupled to the combination circuitry 470 and the resistor 780. In some examples, trim circuitry provides a trim value to the resistor 740. In such examples, the resistance of the resistor 740 is set responsive to the trim value.

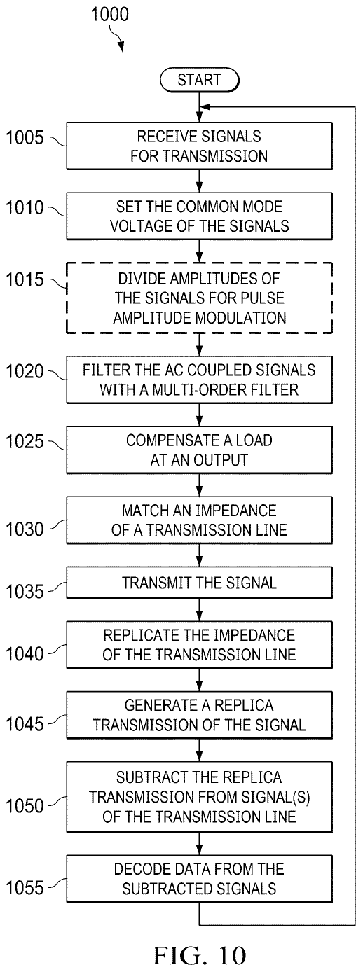

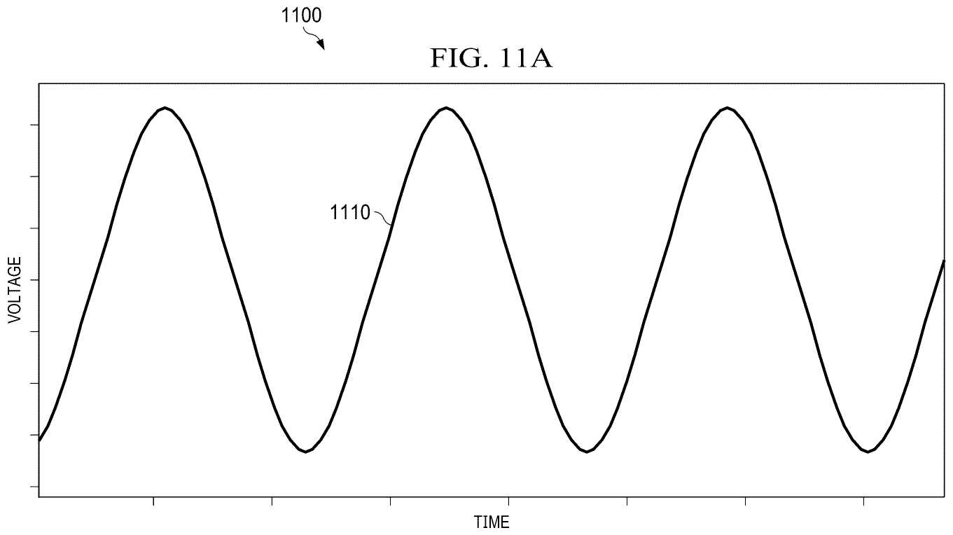

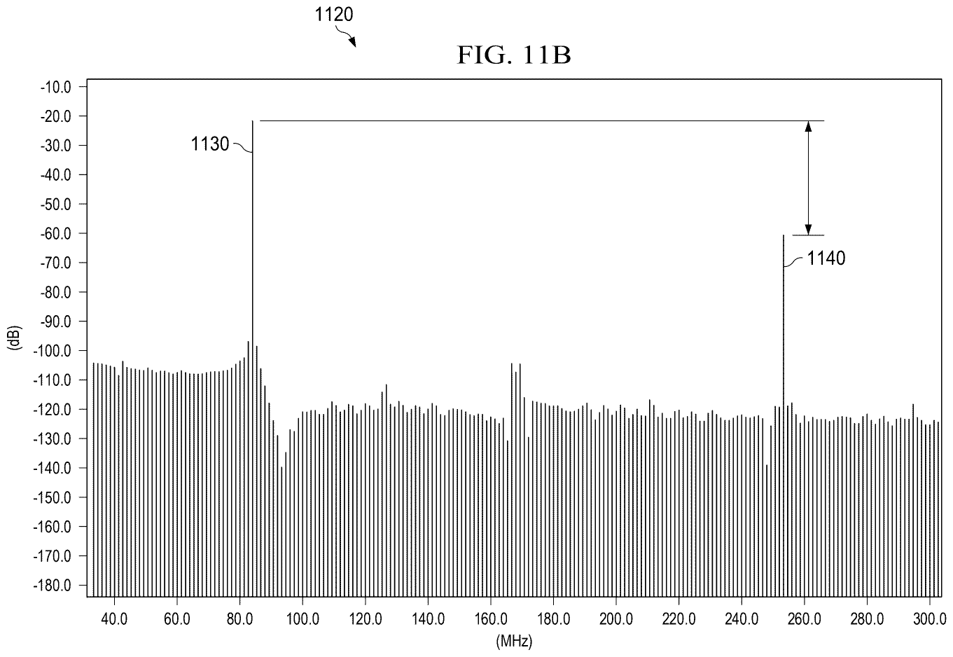

Example operations of the transmitter circuitry 420 of FIG. 7, the load circuitry 460 of FIG. 7, and the combination circuitry 470 of FIG. 7 are illustrated and described in connection with FIGS. 10, 11A, and 11B.

FIG. 8 is a schematic diagram of an example of the transmitter circuitry 420 of FIGS. 4, 5, 6, and 7. The example transmitter circuitry 420 of FIG. 8 includes the AC coupler circuitry 710 of FIG. 7, the filter circuitry 720 of FIG. 7, and the source follower circuitry 730 of FIG. 7. The example AC coupler circuitry 710 of FIG. 8 includes a first example capacitor 803, a second example capacitor 806, a first example resistor 809, a third example capacitor 812, a fourth example capacitor 815, a fifth example capacitor 818, a second example resistor 821, and a sixth example capacitor 824. The example filter circuitry 720 of FIG. 8 includes a first example transistor 827, a second example transistor 830, a first example resistor 833, a third example transistor 836, a fourth example transistor 839, a first example capacitor 842, a fifth example transistor 845, a sixth example transistor 848, a second example capacitor 851, a second example resistor 854, and a third example resistor 857. The example source follower circuitry 730 of FIG. 8 includes a first example transistor 860, a second example transistor 863, an example capacitor 866, an example resistor 869, a third example transistor 872, a fourth example transistor 875, a fifth example transistor 878, and a sixth example transistor 881.

The AC coupler circuitry 710 has a first input, a second input, a third input, a fourth input, a first output, and a second output. The first, second, third, and fourth inputs of the AC coupler circuitry 710 (INP₀, INP_{N}, INM₀, INM_{N}) are structured to be coupled to a digital signal source. The digital signal source provides a differential pair of digital signals at the first and second inputs of the transmitter circuitry 420. For example, the serializer 410 of FIG. 4 provides a serial data stream for transmission across the communication channel 610 of FIG. 6. The first and second outputs of the AC coupler circuitry 710 (CD_OUTP, CD_OUTM) are coupled to the filter circuitry 720.

The filter circuitry 720 has a first input, a second input, a first output, and a second output. The first and second inputs of the filter circuitry 720 are coupled to the AC coupler circuitry 710 (CD_OUTP, CD_OUTM). The first and second outputs of the filter circuitry 720 (BQ_OUTP, BQ_OUTM) are coupled to the source follower circuitry 730.

The source follower circuitry 730 has a first input, a second input, a first output, and a second output. The first and second inputs of the source follower circuitry 730 are coupled to the filter circuitry 720 (BQ_OUTP, BQ_OUTM). The first output of the source follower circuitry 730 (OUTP_Z) is structured to be coupled to the resistors 740, 770 of FIG. 7. The second output of the source follower circuitry 730 (OUTM_Z) is structured to be coupled to the resistors 750, 780 of FIG. 7.

The capacitor 803 has a first terminal and a second terminal. The first terminal of the capacitor 803 is coupled to the first input of the AC coupler circuitry 710 (INP₀). The second terminal of the capacitor 803 is coupled to the capacitors 806, 812, the resistor 809, and the first output of the AC coupler circuitry 710 (CD_OUTP).

The capacitor 806 has a first terminal and a second terminal. The first terminal of the capacitor 806 is coupled to the second input of the AC coupler circuitry 710 (INP_{N}). The second terminal of the capacitor 806 is coupled to the capacitors 803, 812, the resistor 809, and the first output of the AC coupler circuitry 710 (CD_OUTP).

The resistor 809 has a first terminal and a second terminal. The first terminal of the resistor 809 is coupled to a common mode supply terminal, which provides a common mode voltage (V_{CM}). The second terminal of the resistor 809 is coupled to the capacitors 803, 806, 812 and the first output of the AC coupler circuitry 710 (CD_OUTP).

The capacitor 812 has a first terminal and a second terminal. The first terminal of the capacitor 812 is coupled to the common mode supply terminal, which provides the common mode voltage. The second terminal of the capacitor 812 is coupled to the capacitors 803, 806, the resistor 809, and the first output of the AC coupler circuitry 710 (CD_OUTP). In some examples, the capacitor 812 has a trim input. In such examples, trim circuitry provides a trim value to the capacitor 812. The trim value sets the capacitance of the capacitor 812. Such capacitors are referred to as trimmable capacitors.

The capacitor 815 has a first terminal and a second terminal. The first terminal of the capacitor 815 is coupled to the third input of the AC coupler circuitry 710 (INM₀). The second terminal of the capacitor 815 is coupled to the capacitors 818, 824, the resistor 821, and the second output of the AC coupler circuitry 710 (CD_OUTM).

The capacitor 818 has a first terminal and a second terminal. The first terminal of the capacitor 818 is coupled to the fourth input of the AC coupler circuitry 710 (INM_{N}). The second terminal of the capacitor 818 is coupled to the capacitors 815, 824, the resistor 821, and the second output of the AC coupler circuitry 710 (CD_OUTM).

The resistor 821 has a first terminal and a second terminal. The first terminal of the resistor 821 is coupled to the common mode supply terminal, which provides the common mode voltage. The second terminal of the resistor 821 is coupled to the capacitors 815, 818, 824 and the second output of the AC coupler circuitry 710 (CD_OUTM).

The capacitor 824 has a first terminal and a second terminal. The first terminal of the capacitor 824 is coupled to the common mode supply terminal, which provides the common mode voltage. The second terminal of the capacitor 824 is coupled to the capacitors 815, 818, the resistor 821, and the second output of the AC coupler circuitry 710 (CD_OUTM). In some examples, the capacitor 824 has a trim input. In such examples, trim circuitry provides a trim value to the capacitor 824. The trim value sets the capacitance of the capacitor 824. Such capacitors are referred to as trimmable capacitors.

The transistor 827 has a first terminal, a second terminal, and a control terminal. The first terminal of the transistor 827 is coupled to the resistor 833 and the transistor 836. The second terminal of the transistor 827 is coupled to the common terminal, which provides the common potential. The control terminal of the transistor 827 is coupled to a bias supply terminal, which provides a bias voltage (V_{BIAS}).

The transistor 830 has a first terminal, a second terminal, and a control terminal. The first terminal of the transistor 830 is coupled to the resistor 833 and the transistor 839. The second terminal of the transistor 830 is coupled to the common terminal, which provides the common potential. The control terminal of the transistor 830 is coupled to the bias supply terminal, which provides the bias voltage.

The resistor 833 has a first terminal and a second terminal. The first terminal of the resistor 833 is coupled to the transistors 827, 836. The second terminal of the resistor 833 is coupled to the transistors 830, 839. In some examples, the resistor 833 has a trim input. In such examples, trim circuitry provides a trim value to the resistor 833. The trim value sets the resistance of the resistor 833. Such resistors are referred to as trimmable resistors.

The transistor 836 has a first terminal, a second terminal, and a control terminal. The first terminal of the transistor 836 is coupled to the capacitor 842 and the transistor 845. The second terminal of the transistor 836 is coupled to the transistor 827 and the resistor 833. The control terminal of the transistor 836 is coupled to the first output of the AC coupler circuitry 710 (CD_OUTP).

The transistor 839 has a first terminal, a second terminal, and a control terminal. The first terminal of the transistor 839 is coupled to the capacitor 842 and the transistor 848. The second terminal of the transistor 839 is coupled to the transistor 830 and the resistor 833. The control terminal of the transistor 839 is coupled to the second output of the AC coupler circuitry 710 (CD_OUTM).

The resistor 842 has a first terminal and a second terminal. The first terminal of the capacitor 842 is coupled to the transistors 836, 845. The second terminal of the capacitor 842 is coupled to the transistors 839, 848. In some examples, the capacitor 842 has a trim input. In such examples, trim circuitry provides a trim value to the capacitor 842. The trim value sets the capacitance of the capacitor 842. Such capacitors are referred to as trimmable capacitors.

The transistor 845 has a first terminal, a second terminal, and a control terminal. The first terminal of the transistor 845 is coupled to the transistor 848, the capacitor 851, the resistor 854, and the first output of the filter circuitry 720 (BQ_OUTM). The second terminal of the transistor 845 is coupled to the transistor 836 and the capacitor 842. The control terminal of the transistor 845 is coupled to the transistor 848, the capacitor 851, the resistor 857, and the second output of the filter circuitry 720 (BQ_OUTP).

The transistor 848 has a first terminal, a second terminal, and a control terminal. The first terminal of the transistor 848 is coupled to the transistor 845, the capacitor 851, the resistor 857, and the second output of the filter circuitry 720 (BQ_OUTP). The second terminal of the transistor 848 is coupled to the transistor 839 and the capacitor 842. The control terminal of the transistor 848 is coupled to the transistor 845, the capacitor 851, the resistor 854, and the first output of the filter circuitry 720 (BQ_OUTM).

The capacitor 851 has a first terminal and a second terminal. The first terminal of the capacitor 851 is coupled to the transistors 845, 848, the resistor 854, and the first output of the filter circuitry 720 (BQ_OUTM). The second terminal of the capacitor 851 is coupled to the transistors 845, 848, the resistor 854, and the second output of the filter circuitry 720 (BQ_OUTP). In some examples, the capacitor 851 has a trim input. In such examples, trim circuitry provides a trim value to the capacitor 851. The trim value sets the capacitance of the capacitor 851. Such capacitors are referred to as trimmable capacitors.

The resistor 854 has a first terminal and a second terminal. The first terminal of the resistor 854 is coupled to a supply terminal, which provides a supply voltage (e.g., V_{DD}, AVDD, etc.). The second terminal of the resistor 854 is coupled to the transistors 845, 848, the capacitor 851, and the first output of the filter circuitry 720 (BQ_OUTM).

The resistor 857 has a first terminal and a second terminal. The first terminal of the resistor 857 is coupled to the supply terminal, which provides the supply voltage. The second terminal of the resistor 857 is coupled to the transistors 845, 848, the capacitor 851, and the second output of the filter circuitry 720 (BQ_OUTP).

The transistor 860 has a first terminal, a second terminal, and a control terminal. The first terminal of the transistor 860 is coupled to the capacitor 866, the resistor 869, and the transistor 872. The second terminal of the transistor 860 is coupled to the common terminal, which provides the common potential. The control terminal of the transistor 860 is coupled to the bias supply terminal, which provides the bias voltage.

The transistor 863 has a first terminal, a second terminal, and a control terminal. The first terminal of the transistor 863 is coupled to the capacitor 866, the resistor 869, and the transistor 875. The second terminal of the transistor 863 is coupled to the common terminal, which provides the common potential. The control terminal of the transistor 863 is coupled to the bias supply terminal, which provides the bias voltage.

The capacitor 866 has a first terminal and a second terminal. The first terminal of the capacitor 866 is coupled to the transistors 860, 872 and the resistor 869. The second terminal of the capacitor 866 is coupled to the transistors 863, 875 and the resistor 869.

The resistor 869 has a first terminal and a second terminal. The first terminal of the resistor 869 is coupled to the transistors 860, 872 and the capacitor 866. The second terminal of the resistor 869 is coupled to the transistors 863, 875 and the capacitor 866.

The transistor 872 has a first terminal, a second terminal, and a control terminal. The first terminal of the transistor 872 is coupled to the transistors 875, 878 and the first output of the source follower circuitry 730 (OUTP_Z). The second terminal of the transistor 872 is coupled to the transistor 860, the capacitor 866, and the resistor 869. The control terminal of the transistor 872 is coupled to the transistors 875, 881 and the second output of the source follower circuitry 730 (OUTM_Z).

The transistor 875 has a first terminal, a second terminal, and a control terminal. The first terminal of the transistor 875 is coupled to the transistors 872, 881 and the second output of the source follower circuitry 730 (OUTM_Z). The second terminal of the transistor 875 is coupled to the transistor 863, the capacitor 866, and the resistor 869. The control terminal of the transistor 875 is coupled to the transistors 872, 878 and the first output of the source follower circuitry 730 (OUTP_Z).

The transistor 878 has a first terminal, a second terminal, and a control terminal. The first terminal of the transistor 878 is coupled to the supply terminal, which provides the supply voltage. The second terminal of the transistor 878 is coupled to the transistors 872, 875 and the first output of the source follower circuitry 730 (OUTP_Z). The control terminal of the transistor 878 is coupled to the first output of the filter circuitry 720 (BQ_OUTM).

The transistor 881 has a first terminal, a second terminal, and a control terminal. The first terminal of the transistor 881 is coupled to the supply terminal, which provides the supply voltage. The second terminal of the transistor 881 is coupled to the transistors 872, 875 and the second output of the source follower circuitry 730 (OUTM_Z). The control terminal of the transistor 881 is coupled to the second output of the filter circuitry 720 (BQ_OUTP).

In the example of FIG. 8, the transistors 827, 830, 836, 839, 845, 848, 860, 863, 872, 875, 878, 881 are n-channel metal-oxide semiconductor field-effect transistors (MOSFETs). Alternatively, the transistors 827, 830, 836, 839, 845, 848, 860, 863, 872, 875, 878, 881 may be n-channel field-effect transistors (FETs), n-channel insulated-gate bipolar transistors (IGBTs), n-channel junction field effect transistors (JFETs), NPN bipolar junction transistors (BJTs) or, with slight modifications, p-type equivalent devices. The transistors 827, 830, 836, 839, 845, 848, 860, 863, 872, 875, 878, 881 may be depletion mode devices, drain-extended devices, enhancement mode devices, natural transistors or other type of device structure transistors. Furthermore, the transistors 827, 830, 836, 839, 845, 848, 860, 863, 872, 875, 878, 881 may be implemented in/over a silicon substrate (Si), a silicon carbide substrate (SiC), a gallium nitride substrate (GaN) or a gallium arsenide substrate (GaAs).

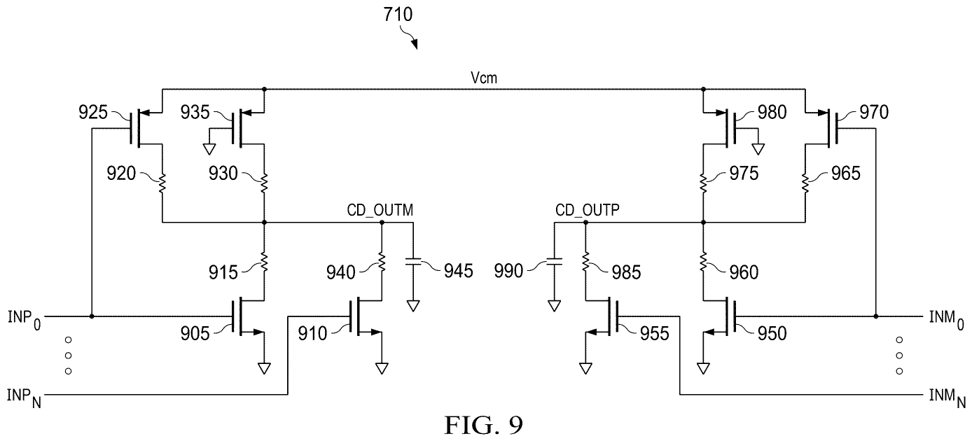

FIG. 9 is a schematic diagram of an example of the AC coupler circuitry 710 of FIGS. 7 and 8. In the example of FIG. 9, the AC coupler circuitry 710 includes a first transistor 905, a second transistor 910, a first resistor 915, a second resistor 920, a third transistor 925, a third resistor 930, a fourth transistor 935, a fourth resistor 940, a first capacitor 945, a fifth transistor 950, a sixth transistor 955, a fifth resistor 960, a sixth resistor 965, a seventh transistor 970, a seventh resistor 975, an eighth transistor 980, an eighth resistor 985, and a second capacitor 990.

The AC coupler circuitry 710 has a first input, a second input, a third input, a fourth input, a first output, and a second output. The first, second, third, and fourth inputs of the AC coupler circuitry 710 (INP₀, INP_{N}, INM₀, INM_{N}) are structured to be coupled to a digital signal source. The digital signal source provides a differential pair of digital signals at the first and second inputs of the transmitter circuitry 420. For example, the serializer 410 of FIG. 4 provides a serial data stream for transmission across the communication channel 610 of FIG. 6. The first and second outputs of the AC coupler circuitry 710 (CD_OUTP, CD_OUTM) are coupled to the filter circuitry 720.

The transistor 905 has a first terminal, a second terminal, and a control terminal. The first terminal of the transistor 905 is coupled to the resistor 915. The second terminal of the transistor 905 is coupled to the common terminal, which provides the common potential. The control terminal of the transistor 905 is coupled to the transistor 925 and the first input of the AC coupler circuitry 710 (INP₀).

The transistor 910 has a first terminal, a second terminal, and a control terminal. The first terminal of the transistor 910 is coupled to the resistor 940. The second terminal of the transistor 910 is coupled to the common terminal, which provides the common potential. The control terminal of the transistor 910 is coupled to the second input of the AC coupler circuitry 710 (INP_{N}).

The resistor 915 has a first terminal and a second terminal. The first terminal of the resistor 915 is coupled to the resistors 920, 930, 940, the capacitor 945, and the second output of the AC coupler circuitry 710 (CD_OUTM). The second terminal of the resistor 915 is coupled to the transistor 910.

The resistor 920 has a first terminal and a second terminal. The first terminal of the resistor 920 is coupled to the transistor 925. The second terminal of the resistor 920 is coupled to the resistors 915, 930, 940, the capacitor 945, and the second output of the AC coupler circuitry 710 (CD_OUTM).

The transistor 925 has a first terminal, a second terminal, and a control terminal. The first terminal of the transistor 925 is coupled to a common mode supply terminal, which provides a common mode voltage (V_{CM}). The second terminal of the transistor 925 is coupled to the resistor 920. The control terminal of the transistor 925 is coupled to the transistor 905 and the first input of the AC coupler circuitry 710 (INP₀).

The resistor 930 has a first terminal and a second terminal. The first terminal of the resistor 930 is coupled to the transistor 935. The second terminal of the resistor 930 is coupled to the resistors 915, 920, 940, the capacitor 945, and the second output of the AC coupler circuitry 710 (CD_OUTM).

The transistor 935 has a first terminal, a second terminal, and a control terminal. The first terminal of the transistor 935 is coupled to the common mode supply terminal, which provides the common mode voltage (V_{CM}). The second terminal of the transistor 935 is coupled to the resistor 930. The control terminal of the transistor 935 is coupled to the common terminal, which provides the common potential.

The resistor 940 has a first terminal and a second terminal. The first terminal of the resistor 940 is coupled to the resistors 915, 920, 930, the capacitor 945, and the second output of the AC coupler circuitry 710 (CD_OUTM). The second terminal of the resistor 940 is coupled to the transistor 910.

The capacitor 945 has a first terminal and a second terminal. The first terminal of the capacitor 945 is coupled to the resistors 915, 920, 930, 940 and the second output of the AC coupler circuitry 710 (CD_OUTM). The second terminal of the capacitor 945 is coupled to the common potential, which provides the common potential.

The transistor 950 has a first terminal, a second terminal, and a control terminal. The first terminal of the transistor 950 is coupled to the resistor 960. The second terminal of the transistor 950 is coupled to the common terminal, which provides the common potential. The control terminal of the transistor 950 is coupled to the transistor 970 and the third input of the AC coupler circuitry 710 (INM₀).

The transistor 955 has a first terminal, a second terminal, and a control terminal. The first terminal of the transistor 955 is coupled to the resistor 985. The second terminal of the transistor 955 is coupled to the common terminal, which provides the common potential. The control terminal of the transistor 955 is coupled to the fourth input of the AC coupler circuitry 710 (INM_{N}).

The resistor 960 has a first terminal and a second terminal. The first terminal of the resistor 960 is coupled to the resistors 965, 975, 985, the capacitor 990, and the first output of the AC coupler circuitry 710 (CD_OUTP). The second terminal of the resistor 960 is coupled to the transistor 950.

The resistor 965 has a first terminal and a second terminal. The first terminal of the resistor 965 is coupled to the transistor 970. The second terminal of the resistor 965 is coupled to the resistors 960, 975, 985, the capacitor 990, and the first output of the AC coupler circuitry 710 (CD_OUTP).

The transistor 970 has a first terminal, a second terminal, and a control terminal. The first terminal of the transistor 970 is coupled to the common mode supply terminal, which provides the common mode voltage (V_{CM}). The second terminal of the transistor 970 is coupled to the resistor 965. The control terminal of the transistor 970 is coupled to the transistor 950 and the third input of the AC coupler circuitry 710 (INM₀).

The resistor 975 has a first terminal and a second terminal. The first terminal of the resistor 975 is coupled to the transistor 980. The second terminal of the resistor is coupled to the resistors 960, 965, 985, the capacitor 990, and the first output of the AC coupler circuitry 710 (CD_OUTP).

The transistor 980 has a first terminal, a second terminal, and a control terminal. The first terminal of the transistor 980 is coupled to the common mode supply terminal, which provides the common mode voltage (V_{CM}). The second terminal of the transistor 980 is coupled to the resistor 975. The control terminal of the transistor 980 is coupled to the common terminal, which provides the common potential.

The resistor 985 has a first terminal and a second terminal. The first terminal of the resistor 985 is coupled to the resistors 960, 965, 975, the capacitor 990, and the first output of the AC coupler circuitry 710 (CD_OUTP). The second terminal of the resistor 985 is coupled to the transistor 955.

The capacitor 990 has a first terminal and a second terminal. The first terminal of the capacitor 990 is coupled to the resistors 960, 965, 975, 985 and the first output of the AC coupler circuitry 710 (CD_OUTP). The second terminal of the capacitor 990 is coupled to the common terminal, which provides the common potential.

In the example of FIG. 9, the transistors 905, 910, 950, 955 are n-channel MOSFETs. Alternatively, the transistors 905, 910, 950, 955 may be n-channel FETs, n-channel IGBTs, n-channel JFETs, NPN BJTs or, with slight modifications, p-type equivalent devices. In the example of FIG. 9, the transistors 925, 935, 970, 980 are p-channel MOSFETs. Alternatively, the transistors 925, 935, 970, 980 may be p-channel FETs, p-channel IGBTs, p-channel JFETs, PNP BJTs or, with slight modifications, n-type equivalent devices. The transistors 905, 910, 925, 935, 950, 955, 970, 980 may be depletion mode devices, drain-extended devices, enhancement mode devices, natural transistors or other type of device structure transistors. Furthermore, the transistors 905, 910, 925, 935, 950, 955, 970, 980 may be implemented in/over a silicon substrate (Si), a silicon carbide substrate (SiC), a gallium nitride substrate (GaN) or a gallium arsenide substrate (GaAs).

FIG. 10 is a flowchart representative of example machine-readable instructions or example operations 1000 that may be at least one of executed, instantiated, or performed using an example implementation of the transmitter circuitry 420 of FIGS. 4, 5, 6, 7, and 8. The example operations 1000 of FIG. 10 begin at Block 1005 at which the transmitter circuitry 420 receives signals for transmission. In example operations, the transmitter circuitry 420 receives first and second digital input signals (INP, INM) from digital source, such as the serializer 410 of FIGS. 4 and 6. The first and second digital input signals are a pair of differential signals representing a serial data stream for transmission across a communication channel, such as the communication channel 610 of FIG. 6.

The AC coupler circuitry 710 of FIGS. 7, 8, and 9 sets the common mode voltage of the signals. (Block 1010). In some example operations, such as in FIG. 8, the capacitors 803, 806, 812 and the resistor 809 set the first digital input signal in relation to a common mode voltage (V_{CM}). Similarly, the capacitors 815, 818, 824 and the resistor 821 set the second digital input signal in relation to the common mode voltage. Advantageously, the AC coupler circuitry 710 couples the first and second digital signals (INP, INM) to the common mode voltage.

In some example operations, such as in FIG. 9, the resistors 915, 920, 930, 940, 960, 965, 975, 985 of FIG. 9 form resistor divider circuitry. The resistors 915, 920, 930, 940, 960, 965, 975, 985 divide the digital signal (INP₀, INM₀) at the inputs of transmitter circuitry 420 in relation to the common mode voltage at the common mode supply. In some examples, the resistors 915, 920, 930, 940, 960, 965, 975, 985 attenuate the digital signals (INP₀, INM₀) at the inputs of transmitter circuitry 420. In such example operations, the resistances of the resistors 915, 920, 930, 940, 960, 965, 975, 985 and the capacitances of the capacitors 945, 990 of FIG. 9 set the rise and fall times at the output of the AC coupler circuitry 710. Advantageously, in some examples, setting the output resistance and the output capacitance of both the first and second outputs of the AC coupler circuitry 710 equal sets the rise time and fall time at the first and second outputs equal to one another.

In some example operations, as illustrated by the dashed outline, the AC coupler circuitry 710 divides amplitudes of the signals for pulse amplitude modulation (PAM). (Block 1015). In example operations, the transmitter circuitry 420 receives additional digital input signals having varying amplitudes. For example, the capacitors 803, 815 receive the first and second digital signals (INP₀, INM₀) and the capacitors 806, 818 receive third and fourth digital signals (INP_{N}, INM_{N}). In such examples, voltages representing logic levels of the first and second digital signals are different from the logic levels representing the third and fourth digital signals. Such modulation of multiple signals for transmission is referred to as pulse amplitude modulation (PAM). In such example operations, the capacitors 803, 806, 812 divide the combined amplitudes of the first and third digital signals (INP₀, INP_{N}) to scale amplitudes of a first scaled digital signal (CD_OUTP) for transmission. Similarly, the capacitors 815, 818, 824 divide the combined amplitudes of the second and fourth digital signals (INM₀, INM_{N}) to scale amplitudes of a second scaled digital signal (CD_OUTM) for transmission. Advantageously, the capacitors 803, 806, 812, 815, 818, 824 support PAM signaling responsive to scaling the combined magnitude for transmission.

In another example of PAM signaling, the transistors 905, 950 receive the first and second digital signals (INP₀, INM₀) and the transistors 910, 955 receive third and fourth digital signals (INP_{N}, INM_{N}). In such examples, the resistors 915, 920, 930, 940 divide the combined amplitudes of the first and third digital signals (INP₀, INP_{N}) to scale amplitudes of a first scaled digital signal (CD_OUTP) for transmission. Similarly, the resistors 940, 960, 965, 975, 985 divide the combined amplitudes of the second and fourth digital signals (INM₀, INM_{N}) to scale amplitudes of a second scaled digital signal (CD_OUTM) for transmission. Advantageously, the transistors 905, 910, 950, 955 and the resistors 915, 920, 930, 940, 960, 965, 975, 985 support PAM signaling responsive to scaling the combined magnitude for transmission.

The filter circuitry 720 of FIGS. 7 and 8 filters the AC coupled signals with a multi-order filter. (Block 1020). In example operations, the resistors 833, 854, 857 and the transistors 836, 839 amplify the scaled digital signals (CD_OUTP, CD_OUTM) by a direct current (DC) gain (GAIN_{DC}). In some examples, the DC gain of the filter circuitry 720 is responsive to a transconductance of the transistors 836, 839 (gm₁), a first resistance of the resistor 833 (R_{S}), and a second resistance of the resistors 854, 857 (R_{L}). In such examples, the DC gain of the filter circuitry 720 is found using Equation (1). Also, in some examples, the resistors 809, 821, 833 may have trim inputs to tune the DC gain of the filter circuitry 720. In such example operations, the capacitors 842, 851, the transistors 845, 848, and the resistors 854, 857 form a second order filter, which is also referred to as a Bi-Quad filter. In some examples, the natural frequency (F_{N}) and quality factor (Q) of the filter circuitry 720 are responsive to a first capacitance of the capacitor 842 (C₁), a transconductance of the transistors 845, 848 (gm₂), a second capacitance of the capacitor 851 (C₂), and the resistance of the resistors 854, 857 (R_{L}). In such examples, the natural frequency of the filter circuitry 720 is found using Equation (2) and the quality factor of the filter circuitry 720 is found using Equation (3). Also, in some examples, the capacitors 842, 851 may have trim inputs to tune the bandwidth of the filter circuitry 720. The filter circuitry 720 produces first and second filtered signals (BQ_OUTP, BQ_OUTM) responsive to filtering the scaled digital signals.

$${GAIN}_{DC} = \frac{g {m}_{1} {R}_{L}}{g {m}_{1} {R}_{S} + 1} \qquad Equation ( 1 )$$

$${F}_{N} = \sqrt{\frac{g {m}_{2}}{{R}_{L} {C}_{1} {C}_{2}}} \qquad Equation ( 2 )$$

$$Q = \frac{\sqrt{g {m}_{2} {R}_{L} {C}_{1} {C}_{2}}}{{C}_{1} + g {m}_{2} {R}_{L} ( {C}_{2} - {C}_{1} )} \qquad Equation ( 3 )$$

The source follower circuitry 730 of FIGS. 7 and 8 compensates a load at an output. (Block 1025). In example operations, the transistors 878, 881 drive first and second output signals of the source follower circuitry 730 (OUTP_Z, OUTM_Z) responsive to the first and second filtered signals (BQ_OUTP, BQ_OUTM). In such example operations, the transistors 872, 875 are structured as a cross-coupled pair of transistors, which follow the transistors 878, 881. In some examples, the transistors 872, 875 compensate the impedance at the first and second outputs of the source follower circuitry 730 responsive to following the operations of the transistors 878, 881. In some examples, the resistance of the source follower circuitry 730 (R_{OUT_DOWN}) is based on a capacitance of the capacitor 866 (C₃), a resistance of the resistor 869 (Rₛ₁), a transconductance of the transistors 872, 875 (gm₇), a resistance of the transistors 872, 875 (r₀₇), and a frequency(s) of the first and second output signals (OUTP_Z, OUTM_Z). In such examples, the resistance of the source follower circuitry 730 is found using Equation (4). Advantageously, cross coupling the transistors 872, 875 increases the bandwidth of the transmitter circuitry 420 responsive to the frequency contributions of the first and second output signals substantially cancelling out. Advantageously, the capacitor 866 further increases the impedance bandwidth of the transmitter circuitry 420 by decreasing the frequency dependency of the resistance of the source follower circuitry 730.

$${R}_{OUT \_ DOWN} = \frac{{r}_{07} + {R}_{S 1} + g {m}_{7} {r}_{07} {R}_{S 1} + s {C}_{3} {R}_{S 1} {r}_{07}}{( 1 - g {m}_{7} {r}_{07} ) ( s {C}_{3} {R}_{S 1} + 1 )} \qquad Equation ( 4 )$$

The resistor 740 of FIG. 7 matches an impedance of a transmission line. (Block 1030). In example operations, the resistor 740 and the resistance at the output of the source follower circuitry 730 (R_{OUT_DOWN}) are structured to match an impedance of a communication channel, such as the communication channel 610. For example, the resistor 740 has a resistance of forty ohms (Ω) responsive to the resistance of the source follower circuitry 730 being ten ohms and the resistance of the communication channel 610 being fifty ohms. Advantageously, matching the impedance of the communication channel 610 increases power efficiency and reduces reflections.

The transmitter circuitry 420 transmits the signal. (Block 1035). In example operations, the resistor 740 transmits a scaled version of the output signal (OUTP_Z) by driving the communication channel 610. In some examples, the resistor 750 transmits a second scaled version of the output signal (OUTM_Z) to termination circuitry, such as the capacitor 760 and the resistor 765. In other examples, such as when the communication channel 610 is a twisted wire pair, the resistor 750 transmits the second scaled version of the output signal by driving the communication channel 610.

The load circuitry 460 of FIGS. 4, 6, and 7 replicates the impedance of the transmission line. (Block 1040). In example operations, the resistors 770, 780 replicate the decrease in amplitude of the output signals (OUTP_Z, OUTM_Z) by the resistors 740, 750. For example, the resistors 770, 780 have the same resistance as the resistors 740, 750.

The load circuitry 460 of FIGS. 4, 6, and 7 generates a replica transmission of the signal. (Block 1045). In example operations, the resistance of the resistor 790 terminates currents of the output signals at the inputs of the combination circuitry 470. In such example operations, the load circuitry 460 provides a replica of signals transmitted across the communication channel 610. Advantageously, the low impedance output of the source follower circuitry 730 allows the load circuitry 460 to provide a replica of the output signals to the combination circuitry 470.

The combination circuitry 470 of FIGS. 4, 6, and 7a subtracts the replica transmission from signal(s) of the transmission line. (Block 1050). In example operations, the combination circuitry 470 subtracts the replicas of the transmitted signals from signals of the communication channel 610. In such example operations, the combination circuitry 470 provides data from other devices to the receiver circuitry 440. Such cancelation of transmitted signals is referred to as echo cancelation.

The receiver circuitry 440 of FIGS. 4 and 6 decodes data from the subtracted signals. (Block 1055). In example operations, the combination circuitry 470 provides received signals from the communication channel 610 to the receiver circuitry 440. In such example operations, the receiver circuitry 440 amplifies the received signal to account for signal attenuation across the communication channel 610. Control proceeds to return to Block 1005.

Example methods are described with reference to the flowchart illustrated in FIG. 10. However, many other methods of implementing the transmitter circuitry 420 of FIGS. 4, 5, 6, 7, and 8 may also be used in this description. For example, the order of execution of the blocks may be changed, or some of the blocks described may be changed, eliminated, or combined. Similarly, additional operations may be included in the manufacturing process before, in between, or after the blocks shown in the illustrated examples.

FIG. 10A is a plot 1100 of example operations of the transmitter circuitry 420 of FIGS. 4, 6, 7, and 8. In the example of FIG. 11A, the plot 1100 illustrates an example transmitted signal 1110. The transmitted signal 1110 represents a signal transmission across the communication channel 610 by the transmitter circuitry 420. Advantageously, the filter circuitry 720 produces the transmitted signal 1110 responsive to smoothing relatively sharp transitions of the digital input signals. Advantageously, the transmitted signal 1110 is a sinusoidal signal, which is less susceptible to inter-symbol interference (ISI), jitter, and harmonic distortions.

FIG. 11B is a plot 1120 of example operations of the transmitter circuitry 420 of FIGS. 4, 6, 7, and 8 across a frequency spectrum. In the example of FIG. 11B, the plot 1120 has a fundamental frequency 1130 and a harmonic frequency 1140. The fundamental frequency 1130 represents a transmission frequency of a signal by the transmitter circuitry 420. The harmonic frequency 1140 is a multiple of the fundamental frequency 1130. The difference between the power of signals at the fundamental frequency 1130 and the harmonic frequency 1140 is referred to as the spurious free dynamic range (SFDR) of the transmitter circuitry 420. Advantageously, the difference between the power of signals at the fundamental frequency 1130 and the harmonic frequency 1140 allows the receiver circuitry 440 to accurately detect signals of the fundamental frequency 1130.

FIG. 12 is a block diagram of an example of the delay circuitry 520 of FIGS. 5 and 6 and the transmitter circuitry 530 of FIGS. 5 and 6. The example delay circuitry 520 of FIG. 12 includes a first example delay element 1205, a second example delay element 1210, a third example delay element 1215, a fourth example delay element 1220, a fifth example delay element 1225, and a sixth example delay element 1230. The example transmitter circuitry 530 of FIG. 12 includes a first example FFE segment 1235, a second example FFE segment 1240, a third example FFE segment 1245, example impedance compensation circuitry 1250, and example load circuitry 1255.

The delay circuitry 520 has a first input, a second input, a first output, a second output, a third output, a fourth output, a fifth output, and a sixth output. The first and second inputs of the delay circuitry 520 (INP, INM) are structured to be coupled to a digital signal source. The digital signal source provides a differential pair of digital signals at the first and second inputs of the delay circuitry 520. For example, the serializer 510 of FIG. 5 provides a serial data stream for transmission across the communication channel 610 of FIG. 6. The first and fourth outputs of the delay circuitry 520 (INP_SEG0, INM_SEG0) are coupled to the FFE segment 1235. The second and fifth outputs of the delay circuitry 520 (INP_SEG1, INM_SEG1) are coupled to the FFE segment 1240. The third and sixth outputs of the delay circuitry 520 (INP_SEGN, INM_SEGN) are coupled to the FFE segment 1245.

The transmitter circuitry 530 has a first input, a second input, a third input, a fourth input, a fifth input, a sixth input, a first output, and a second output. The first, second, third, fourth, fifth, and sixth inputs of the transmitter circuitry 530 are coupled to the delay circuitry 520. The first and second outputs of the transmitter circuitry 530 (OUTP, OUTM) are structured to be coupled to a communication channel, such as the communication channel 610.

The delay element 1205 has an input and an output. The input of the delay element 1205 is coupled to the delay elements 1210, 1215 and the first input of the delay circuitry 520 (INP). The output of the delay element 1205 is coupled to the FFE segment 1235.

The delay element 1210 has an input and an output. The input of the delay element 1210 is coupled to the delay elements 1205, 1215 and the first input of the delay circuitry 520 (INP). The output of the delay element 1210 is coupled to the FFE segment 1240.

The delay element 1215 has an input and an output. The input of the delay element 1215 is coupled to the delay elements 1205, 1210 and the first input of the delay circuitry 520 (INP). The output of the delay element 1215 is coupled to the FFE segment 1245.

The delay element 1220 has an input and an output. The input of the delay element 1220 is coupled to the delay elements 1225, 1230 and the second input of the delay circuitry 520 (INM). The output of the delay element 1220 is coupled to the FFE segment 1235.

The delay element 1225 has an input and an output. The input of the delay element 1225 is coupled to the delay elements 1220, 1230 and the second input of the delay circuitry 520 (INM). The output of the delay element 1225 is coupled to the FFE segment 1240.

The delay element 1230 has an input and an output. The input of the delay element 1230 is coupled to the delay elements 1220, 1225 and the second input of the delay circuitry 520 (INM). The output of the delay element 1230 is coupled to the FFE segment 1245.

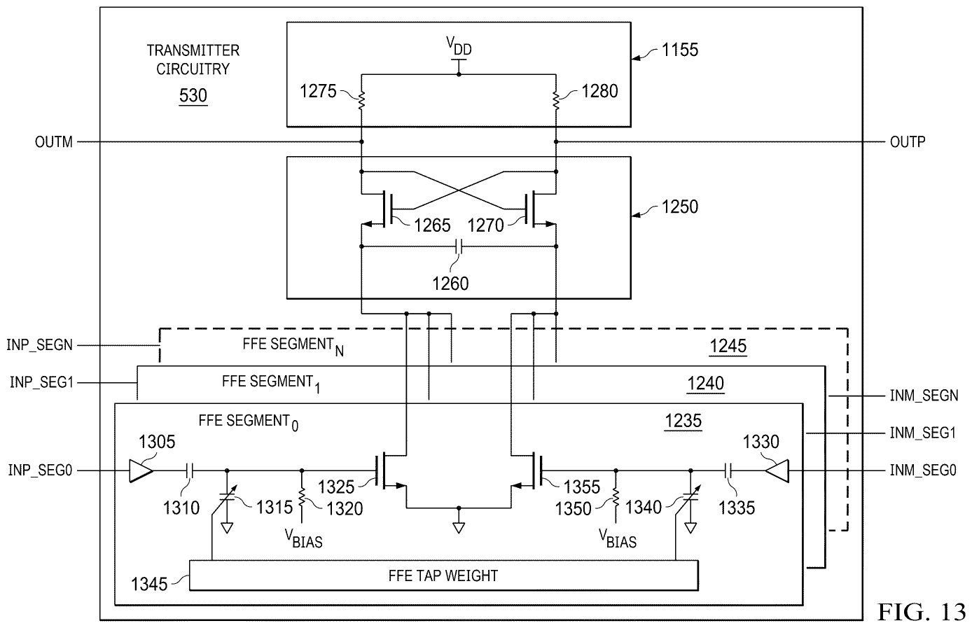

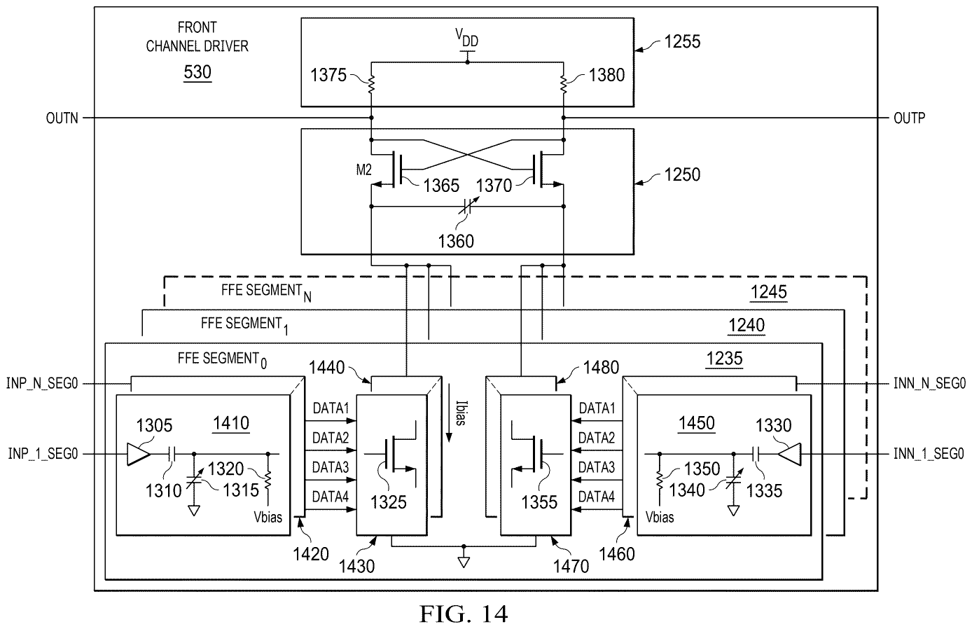

The FFE segment 1235 has a first input, a second input, a first output, and a second output. The first input of the FFE segment 1235 is coupled to the delay element 1205. The second input of the FFE segment 1235 is coupled to the delay element 1220. The first output of the FFE segment 1235 is coupled to the FFE segments 1240, 1245 and the impedance compensation circuitry 1250. The second output of the FFE segment 1235 is coupled to the FFE segments 1240, 1245 and the impedance compensation circuitry 1250. Examples of the FFE segment 1235 are further illustrated and described in connection with FIGS. 13 and 14.

The FFE segment 1240 has a first input, a second input, a first output, and a second output. The first input of the FFE segment 1240 is coupled to the delay element 1210. The second input of the FFE segment 1240 is coupled to the delay element 1225. The first output of the FFE segment 1240 is coupled to the FFE segments 1235, 1245 and the impedance compensation circuitry 1250. The second output of the FFE segment 1240 is coupled to the FFE segments 1235, 1245 and the impedance compensation circuitry 1250. Examples of the FFE segment 1240 are further illustrated and described in connection with FIGS. 13 and 14.

The FFE segment 1245 has a first input, a second input, a first output, and a second output. The first input of the FFE segment 1245 is coupled to the delay element 1215. The second input of the FFE segment 1245 is coupled to the delay element 1230. The first output of the FFE segment 1245 is coupled to the FFE segments 1235, 1240 and the impedance compensation circuitry 1250. The second output of the FFE segment 1245 is coupled to the FFE segments 1235, 1240 and the impedance compensation circuitry 1250. Examples of the FFE segment 1245 are further illustrated and described in connection with FIGS. 13 and 14.

The impedance compensation circuitry 1250 has a first input, a second input, a first output, and a second output. The first and second inputs of the impedance compensation circuitry 1250 are coupled to the FFE segments 1235, 1240, 1245. The first output of the impedance compensation circuitry 1250 is coupled to the load circuitry 1255 and the first output of the transmitter circuitry 530 (OUTP). The second output of the impedance compensation circuitry 1250 is coupled to the load circuitry 1255 and the second output of the transmitter circuitry 530 (OUTM). An example of the impedance compensation circuitry 1250 is further illustrated and described in connection with FIGS. 13 and 14.

The load circuitry 1255 has a first output and a second output. The first output of the load circuitry 1255 is coupled to the impedance compensation circuitry 1250 and the first output of the transmitter circuitry 530 (OUTP). The second output of the load circuitry 1255 is coupled to the impedance compensation circuitry 1250 and the second output of the transmitter circuitry 530 (OUTM).

Example operations of the delay circuitry 520 of FIG. 12 and the transmitter circuitry 530 of FIG. 12 are illustrated and described in connection with FIG. 12.

FIG. 13 is a schematic diagram of an example of the transmitter circuitry 530 of FIGS. 5, 6, and 12. The example transmitter circuitry 530 of FIG. 13 includes the FFE segments 1235, 1240, 1245 of FIG. 12, the impedance compensation circuitry 1250 of FIG. 12, and the load circuitry 1255 of FIG. 12. The example FFE segment 1235 of FIG. 13 includes a first example buffer 1305, a first example capacitor 1310, a second example capacitor 1315, a first example resistor 1320, a first example transistor 1325, a second buffer 1330, a third example capacitor 1335, a fourth example capacitor 1340, example trim circuitry 1345, a second example resistor 1350, and a second example transistor 1355. The example impedance compensation circuitry 1250 of FIG. 13 includes an example capacitor 1360, a first example transistor 1365, and a second example transistor 1370. The example load circuitry 1255 of FIG. 13 includes a first example resistor 1375 and a second example resistor 1380.

The transmitter circuitry 530 has a first input, a second input, a third input, a fourth input, a fifth input, a sixth input, a first output, and a second output. The first, second, third, fourth, fifth, and sixth inputs of the transmitter circuitry 530 are coupled to the delay circuitry 520. The first and second outputs of the transmitter circuitry 530 (OUTP, OUTM) are structured to be coupled to a communication channel, such as the communication channel 610 of FIG. 6.

The buffer 1305 has an input and an output. The input of the buffer 1305 is coupled to the first input of the transmitter circuitry 530 (INP_SEG0). The output of the buffer 1305 is coupled to the capacitor 1310.

The capacitor 1310 has a first terminal and a second terminal. The first terminal of the capacitor 1310 is coupled to the buffer 1305. The second terminal of the capacitor 1310 is coupled to the capacitor 1315, the resistor 1320, and the transistor 1325.

The capacitor 1315 has a first terminal, a second terminal, and a trim input. The first terminal of the capacitor 1315 is coupled to the capacitor 1310, the resistor 1320, and the transistor 1325. The second terminal of the capacitor 1315 is coupled to the common terminal, which provides the common potential. The trim input of the capacitor 1315 is coupled to the trim circuitry 1345.

The resistor 1320 has a first terminal and a second terminal. The first terminal of the resistor 1320 is coupled to the capacitors 1310, 1315 and the transistor 1325. The second terminal of the resistor 1320 is coupled to a bias supply terminal, which provides a bias voltage (V_{BIAS}).

The transistor 1325 has a first terminal, a second terminal, and a control terminal. The first terminal of the transistor 1325 is coupled to the FFE segments 1240, 1245, the capacitor 1360, and the transistor 1365. The second terminal of the transistor 1325 is coupled to the common terminal, which provides the common potential. The control terminal of the transistor 1325 is coupled to the capacitors 1310, 1315 and the resistor 1320.

The buffer 1330 has an input and an output. The input of the buffer 1330 is coupled to the second input of the FFE segment 1235 (INM_SEG0). The output of the buffer 1330 is coupled to the capacitor 1335.

The capacitor 1335 has a first terminal and a second terminal. The first terminal of the capacitor 1335 is coupled to the buffer 1330. The second terminal of the capacitor 1335 is coupled to the capacitor 1340, the resistor 1350, and the transistor 1355.

The capacitor 1340 has a first terminal, a second terminal, and a trim input. The first terminal of the capacitor 1340 is coupled to the capacitor 1335, the resistor 1350, and the transistor 1355. The second terminal of the capacitor 1340 is coupled to the common terminal, which provides the common potential. The trim input of the capacitor 1340 is coupled to the trim circuitry 1345.

The trim circuitry 1345 has a first output and a second output. The first output of the trim circuitry is coupled to the capacitor 1315. The second output of the trim circuitry 1345 is coupled to the capacitor 1340.

The resistor 1350 has a first terminal and second terminal. The first terminal of the resistor 1350 is coupled to the capacitors 1335, 1340 and the transistor 1355. The second terminal of the resistor 1350 is coupled is coupled to the bias supply terminal, which provides the supply voltage.

The transistor 1355 has a first terminal, a second terminal, and a control terminal. The first terminal of the transistor 1355 is coupled to the FFE segments 1240, 1245, the capacitor 1360, and the transistor 1370. The second terminal of the transistor 1355 is coupled to the common terminal, which provides the common potential. The control terminal of the transistor 1355 is coupled to the capacitors 1335, 1340 and the resistor 1350.

The capacitor 1360 has a first terminal and a second terminal. The first terminal of the capacitor 1360 is coupled to the FFE segments 1235, 1240, 1245 and the transistors 1325, 1365. The second terminal of the capacitor 1360 is coupled to the FFE segments 1235, 1240, 1245 and the transistors 1355, 1370. In some examples, the capacitor 1360 has a trim input. In such examples, trim circuitry provides a trim value to the capacitor 1360. The trim value sets the capacitance of the capacitor 1360. Such capacitors are referred to as trimmable capacitors.

The transistor 1365 has a first terminal, a second terminal, and a control terminal. The first terminal of the transistor 1365 is coupled to the transistor 1370, the resistor 1375, and the second output of the transmitter circuitry 530 (OUTM). The second terminal of the transistor 1365 is coupled to the FFE segments 1235, 1240, 1245, the transistor 1325, and the capacitor 1360. The control terminal of the transistor 1365 is coupled to the transistor 1370, the resistor 1380, and the first output of the transmitter circuitry 530 (OUTP).

The transistor 1370 has a first terminal, a second terminal, and a control terminal. The first terminal of the transistor 1370 is coupled to the transistor 1365, the resistor 1380, and the first output of the transmitter circuitry 530. The second terminal of the transistor 1370 is coupled to the FFE segments 1235, 1240, 1245, the transistor 1355, and the capacitor 1360. The control terminal of the transistor 1370 is coupled to the transistor 1365, the resistor 1375, and the second output of the transmitter circuitry 530 (OUTM).

The resistor 1375 has a first terminal and a second terminal. The first terminal of the resistor 1375 is coupled to the supply terminal, which provides the supply voltage. The second terminal of the resistor 1375 is coupled to the transistors 1365, 1370 and the second output of the transmitter circuitry 530 (OUTM).

The resistor 1380 has a first terminal and a second terminal. The first terminal of the resistor 1380 is coupled to the supply terminal, which provides the supply voltage. The second terminal of the resistor 1380 is coupled to the transistors 1365, 1370 and the first output of the transmitter circuitry 530 (OUTP).

In the example of FIG. 13, the transistors 1325, 1355, 1365, 1370 are n-channel MOSFETs. Alternatively, the transistors 1325, 1355, 1365, 1370 may be n-channel FETs, n-channel IGBTs, n-channel JFETs, NPN BJTs or, with slight modifications, p-type equivalent devices. The transistors 1325, 1355, 1365, 1370 may be depletion mode devices, drain-extended devices, enhancement mode devices, natural transistors or other type of device structure transistors. Furthermore, the transistors 1325, 1355, 1365, 1370 may be implemented in/over a silicon substrate (Si), a silicon carbide substrate (SiC), a gallium nitride substrate (GaN) or a gallium arsenide substrate (GaAs).

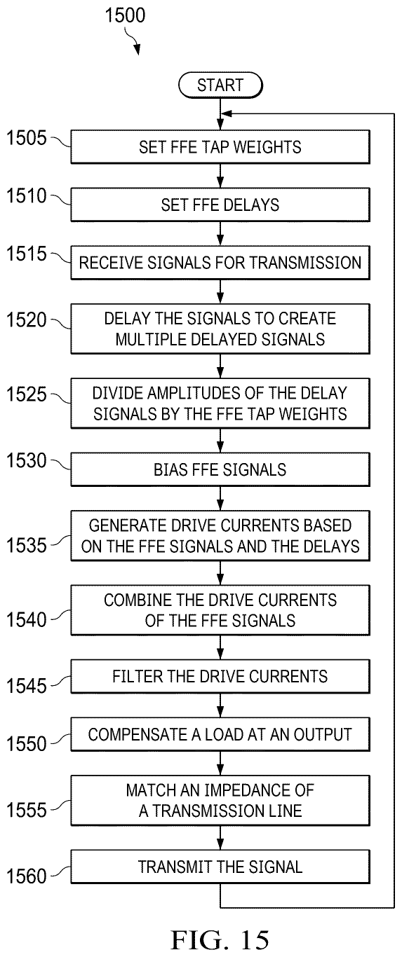

Example operations of the FFE segments 1235, 1240, 1245 of FIG. 13, the impedance compensation circuitry 1250 of FIG. 13, and the load circuitry 1255 of FIG. 13 are illustrated and described in connection with FIG. 15.

FIG. 14 is a schematic diagram of another example of the transmitter circuitry 530 of FIGS. 5, 6, 12, and 13. The example transmitter circuitry 530 of FIG. 14 includes the FFE segments 1235, 1240, 1245 of FIG. 12, the impedance compensation circuitry 1250 of FIG. 12, and the load circuitry 1255 of FIG. 12. The example FFE segment 1235 of FIG. 14 includes first example multiplex segment 1410, a second example multiplex segment 1420, a first example current drive segment 1430, a second example current drive segment 1440, a third example multiplex segment 1450, a fourth example multiplex segment 1460, a third example current drive segment 1470, and a fourth example current drive segment 1480.

The example multiplex segment 1410 of FIG. 14 includes the buffer 1305 of FIG. 13, the capacitors 1310, 1315 of FIG. 13, and the resistor 1320 of FIG. 13. The example current drive segment 1440 of FIG. 14 includes the transistor 1325 of FIG. 13. The example multiplex segment 1450 of FIG. 14 includes the buffer 1330 of FIG. 13, the capacitors 1335, 1340 of FIG. 13, and the resistor 1350 of FIG. 13. The example current drive segment 1470 of FIG. 14 includes the transistor 1355 of FIG. 13.

In FIG. 13, the transmitter circuitry 530 is structured to implement PAM using the multiplex segments 1410, 1420, 1450, 1460 and the current drive segments 1430, 1440, 1470, 1480. In some examples, the transmitter circuitry 530 may be modified to include any number of multiplex segments or current drive segments to support additional signals. Example operations of the FFE segments 1235, 1240, 1245 of FIG. 14, the impedance compensation circuitry 1250 of FIG. 14, and the load circuitry 1255 of FIG. 14 are illustrated and described in connection with FIG. 15.

FIG. 15 is a flowchart representative of example machine-readable instructions or example operations 1500 that may be at least one of executed, instantiated, or performed using an example implementation of the transmitter circuitry 530 of FIGS. 5, 6, 12, 13, and 14. The example operations 1500 of FIG. 15 begin at Block 1505 at which the capacitors 1315, 1340 set FFE tap weights. In example operations, the capacitors 1310, 1315 form first voltage divider circuitry and the capacitors 1335, 1340 form second voltage divider circuitry. In such example operations, the ratio of capacitances of the capacitors 1310, 1335 to the capacitors 1315, 1340 sets the scaling of input signals. In some examples, the FFE segment 1235 includes the trim circuitry 1345 to set capacitances of the capacitors 1315, 1340. In such examples, the scaling of input signals by the capacitors 1310, 1315, 1335, 1340 are referred to as tap weights.

The delay circuitry 520 sets FFE delays. (Block 1510). In example operations, the delay elements 1205, 1220 delay edges of an input signal by a first delay, the delay elements 1210, 1225 delay edges of the input signal by a second delay, and the delay elements 1215, 1230 delay edges of the input signal by a third delay. In such example operations, transmitted signals have a first amplitude until the end of the first delay, a second amplitude until the end of the second delay, and a third amplitude until the end of the third delay. Such a change in the amplitude of a transmission is referred to as feed-forward equalization (FFE). In such examples, the delays of the delay circuitry 520 sequence the FFE segments 1235, 1240, 1245 for FFE.

The transmitter circuitry 530 receives signals for transmission. (Block 1515). In example operations, the transmitter circuitry 530 receives first and second digital input signals (INP, INM) from digital source, such as the serializer 510 of FIGS. 5 and 6. The first and second digital input signals are a pair of differential signals representing a serial data stream for transmission across a communication channel, such as the communication channel 610 of FIG. 6.

The delay circuitry 520 delays the signals to create multiple delayed signals. (Block 1520). In example operations, the delay circuitry 520 sequences the length of current contributions from each of the FFE segments 1235, 1240, 1245 by delay values. For example, the FFE segments 1235, 1240, 1245 begin sinking current responsive to an edge of the input signal. At a first time, after the first delay of the delay elements 1205, 1220, the FFE segment 1235 stops conducting current, which decreases the amplitude of a transmission. At a second time, after the second delay of the delay elements 1210, 1225, the FFE segment 1240 stops conducting current, which further decreases the amplitude of the transmission. At a third time, after the third delay of the delay elements 1215, 1230, the FFE segment 1245 stops conducting current, which ends the transmission. Advantageously, the delay circuitry 520 sequences the current contributions by the FFE segments 1235, 1240, 1245 for FFE. Alternatively, the transmitter circuitry 530 may be modified to sequence currents of the FFE segments 1235, 1240, 1245 using alternative circuitry.

The capacitors 1310, 1315, 1335, 1340 divide amplitudes of the delay signals by the FFE tap weights. (Block 1525). In example operations, the capacitors 1310, 1315 divide the input signal by the ratio of the capacitances and the capacitors 1335, 1340 divide the input signal by the ratio of the capacitances. In such example operations, adjusting the capacitance of the capacitors 1315, 1340 controls the division of the input signals. Advantageously, the division of the input signals by the capacitors 1310, 1315, 1335, 1340 controls the magnitude of the current contribution by the FFE segment 1235. Similarly, adjusting corresponding capacitance ratios of the respective capacitors of the FFE segments 1240, 1245 controls the decrease in amplitude during FFE.

The resistors 1320, 1350 set a bias of FFE signals. (Block 1530). In example operations, the resistors 1320, 1350 couple the bias voltage (V_{BIAS}) to the control terminals of the transistors 1325, 1355. In some examples, the current from the resistors 1320, 1350 decreases switching time of the transistors 1325, 1355 responsive to biasing the control terminal towards a threshold voltage. In other examples, the current from the resistors 1320, 1350 sets the common mode voltage of the divided input signals.

The transistors 1325, 1355 generates drive currents based on the FFE signals and the delays. (Block 1535). In example operations, the divided input signals control the transistors 1325, 1355. In such example operations, the transistors 1325, 1355 sink current from the impedance compensation circuitry 1250 responsive to receiving a divided input signal corresponding to a logic high (e.g., a logical one).

The impedance compensation circuitry 1250 combines the drive currents of the FFE signals. (Block 1540). In example operations, the transistors 1365, 1370 are cross coupled to form a positive feedback loop, which actively compensates the output impedance. Such a feedback loop between 1360 the transistors 1365, 1370 provides summing nodes for currents from the FFE segments 1235, 1240, 1245. In some examples, the summing nodes are referred to as a virtual ground. In such example operations, the transistors 1365, 1370 sequence the supply of the combined currents from the resistors 1375, 1380 responsive to being cross coupled.

The impedance compensation circuitry 1250 filters the drive currents. (Block 1545). In example operations, the capacitor 1360 and the transistors 1365, 1370 filter the drive currents from the FFE segments 1235, 1240, 1245 responsive to being cross coupled.

The impedance compensation circuitry 1250 compensates a load at an output. (Block 1550). In example operations, the resistance of the impedance compensation circuitry 1250 (R_{OUT_DOWN}) is independent of the resistance of a load. The resistance of the impedance compensation circuitry 1250 (R_{OUT_DOWN}) is based on a capacitance of the capacitor 1360 (C), a transconductance of the transistors 1365, 1370 (gm₂), a first resistance of the transistors 1325, 1355 (r₀₁), a second resistance of the transistors 1365, 1370 (r₀₂), and a frequency(s) of the first and second output signals (OUTP, OUTM). In such examples, the resistance of the impedance compensation circuitry 1250 is found using Equation (5). Advantageously, the transistors 1365, 1370 and the capacitor 1360 increase the impedance bandwidth of the transmitter circuitry 530 responsive to compensating for return loss at relatively high frequencies. In such example operations, the impedance at the outputs (OUTP, OUTN) of the transmitter circuitry 530 is set by the resistors 1375, 1380 in parallel to the resistance of the impedance compensation circuitry 1250 (R_{OUT_DOWN}).

$${R}_{OUT\_DOWN} = \frac{r o 1 + r o 2 + g m 2 * r o 1 * r o 2 + s C * r o 1 * r o 2}{( 1 - g m 2 * r o 2 ) ( s C * ro 1 + 1 )} \qquad Equation ( 5 )$$

The load circuitry 1255 matches an impedance of a transmission line. (Block 1555). In example operations, the resistors 1375, 1380 have set resistance, which matches the impedance of the communication channel during positive portions of the signal transmission. In such example operations, the impedance compensation circuitry 1250 matches the impedance of the transmission line for negative portions of the signal transmission.

The transmitter circuitry 530 transmits the signal. (Block 1560). In example operations, the transistors 1365, 1370 drive the communication channel 610 by using currents of the FFE segments 1235, 1240, 1245 through the resistors 1375, 1380. In such example operations, the lack of current conduction by the transistors 1365 allows the voltage of the second output signal (OUTM) to increase. Similarly, the conduction of current by the transistors 1365 pulls down the second output signal responsive to the voltage difference across the resistor 1375. Control proceeds to return to Block 1505.

Example methods are described with reference to the flowchart illustrated in FIG. 15. However, many other methods of implementing the transmitter circuitry 530 of FIGS. 5, 6, 12, 13, and 14 may also be used in this description. For example, the order of execution of the blocks may be changed, or some of the blocks described may be changed, eliminated, or combined. Similarly, additional operations may be included in the manufacturing process before, in between, or after the blocks shown in the illustrated examples.

FIG. 16 is a plot 1600 of example operations of the transmitter circuitry 530 of FIGS. 5, 6, 12, 13, and 14. In the example of FIG. 16, the plot 1600 illustrates a non-cross-coupled impedance 1610 and a cross-coupled impedance 1620 across a range of frequencies. In operation, the non-cross-coupled impedance 1610 decreases as the frequency increases. Such decreases are a responsive to the parasitic capacitances of the FFE segments and load capacitance. In example operations of the transmitter circuitry 530, the cross-coupled impedance 1620 counters the attenuation of the communication channel 610 as the frequency increases. Advantageously, the cross coupled transistors 1365, 1370 of FIGS. 13 and 14 compensates for the attenuation of signals at high frequencies.

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C, (6) B with C, or (7) A with B and with C. As used herein in the context of describing structures, components, items, objects and things, the phrase “at least one of A and B” refers to implementations including any of (1) at least one A, (2) at least one B, or (3) at least one A and at least one B. Similarly, as used herein in the context of describing structures, components, items, objects and things, the phrase “at least one of A or B” refers to implementations including any of (1) at least one A, (2) at least one B, or (3) at least one A and at least one B. As used herein in the context of describing the performance or execution of processes, instructions, actions, activities, etc., the phrase “at least one of A and B” refers to implementations including any of (1) at least one A, (2) at least one B, or (3) at least one A and at least one B. Similarly, as used herein in the context of describing the performance or execution of processes, instructions, actions, activities, etc., the phrase “at least one of A or B” refers to implementations including any of (1) at least one A, (2) at least one B, or (3) at least one A and at least one B.

As used herein, singular references (e.g., “a,” “an,” “first,” “second,” etc.) do not exclude a plurality. The term “a” or “an” object, as used herein, refers to one or more of that object. The terms “a” (or “an”), “one or more,” and “at least one” are used interchangeably herein. Furthermore, although individually listed, a plurality of means, elements, or actions may be implemented by, e.g., the same entity or object. Also, although individual features may be included in different examples or claims, these may possibly be combined, and the inclusion in different examples or claims does not imply that a combination of features is at least one of not feasible or advantageous.

As used herein, unless otherwise stated, the term “above” describes the relationship of two parts relative to Earth. A first part is above a second part, if the second part has at least one part between Earth and the first part. Likewise, as used herein, a first part is “below” a second part when the first part is closer to the Earth than the second part. As noted above, a first part can be above or below a second part with one or more of: other parts therebetween, without other parts therebetween, with the first and second parts touching, or without the first and second parts being in direct contact with one another.

As used in this patent, stating that any part (e.g., a layer, film, area, region, or plate) is in any way on (e.g., positioned on, located on, disposed on, or formed on, etc.) another part, indicates that the referenced part is either in contact with the other part, or that the referenced part is above the other part with one or more intermediate part(s) located therebetween.

As used herein, connection references (e.g., attached, coupled, connected, and joined) may include intermediate members between the elements referenced by at least one of the connection reference or relative movement between those elements unless otherwise indicated. As such, connection references do not necessarily infer that two elements are directly connected or in fixed relation to each other. As used herein, stating that any part is in “contact” with another part is defined to mean that there is no intermediate part between the two parts.

Unless specifically stated otherwise, descriptors such as “first,” “second,” “third,” etc., are used herein without imputing or otherwise indicating any meaning of priority, physical order, arrangement in a list, or ordering in any way, but are merely used as at least one of labels or arbitrary names to distinguish elements for ease of understanding the described examples. In some examples, the descriptor “first” may be used to refer to an element in the detailed description, while the same element may be referred to in a claim with a different descriptor such as “second” or “third.” In such instances, such descriptors are used merely for identifying those elements distinctly within the context of the discussion (e.g., within a claim) in which the elements might, for example, otherwise share a same name.

As used herein, “approximately” and “about” modify their subjects/values to recognize the potential presence of variations that occur in real world applications. For example, “approximately” and “about” may modify dimensions that may not be exact due to at least one of manufacturing tolerances or other real-world imperfections. For example, “approximately” and “about” may indicate such dimensions may be within a tolerance range of +/−10% unless otherwise specified herein.

As used herein, the phrase “in communication,” including variations thereof, encompasses one of or a combination of direct communication or indirect communication through one or more intermediary components, and does not require direct physical (e.g., wired) communication or constant communication, but rather also includes selective communication at least one of periodic intervals, scheduled intervals, aperiodic intervals, or one-time events.

As used herein, “programmable circuitry” is defined to include at least one of (i) one or more special purpose electrical circuits (e.g., an application specific circuit (ASIC)) structured to perform specific operation(s) and including one or more semiconductor-based logic devices (e.g., electrical hardware implemented by one or more transistors), or (ii) one or more general purpose semiconductor-based electrical circuits programmable with instructions to perform one or more specific functions(s) or operation(s) and including one or more semiconductor-based logic devices (e.g., electrical hardware implemented by one or more transistors). Examples of programmable circuitry include programmable microprocessors such as Central Processor Units (CPUs) that may execute first instructions to perform one or more operations or functions, Field Programmable Gate Arrays (FPGAs) that may be programmed with second instructions to at least one of configure or structure the FPGAs to instantiate one or more operations or functions corresponding to the first instructions, Graphics Processor Units (GPUs) that may execute first instructions to perform one or more operations or functions, Digital Signal Processors (DSPs) that may execute first instructions to perform one or more operations or functions, XPUs, Network Processing Units (NPUs) one or more microcontrollers that may execute first instructions to perform one or more operations or functions or integrated circuits such as Application Specific Integrated Circuits (ASICs). For example, an XPU may be implemented by a heterogeneous computing system including multiple types of programmable circuitry (e.g., one or more FPGAs, one or more CPUs, one or more GPUs, one or more NPUs, one or more DSPs, etc., and any combination(s) thereof), and orchestration technology (e.g., application programming interface(s) (API(s)) that may assign computing task(s) to whichever one(s) of the multiple types of programmable circuitry is/are suited and available to perform the computing task(s).

As used herein integrated circuit/circuitry is defined as one or more semiconductor packages containing one or more circuit elements such as transistors, capacitors, inductors, resistors, current paths, diodes, etc. For example, an integrated circuit may be implemented as one or more of an ASIC, an FPGA, a chip, a microchip, programmable circuitry, a semiconductor substrate coupling multiple circuit elements, a system on chip (SoC), etc.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

A device that is “configured to” perform a task or function may be configured (e.g., at least one of programmed or hardwired) at a time of manufacturing by a manufacturer to at least one of perform the function or be configurable (or re-configurable) by a user after manufacturing to perform the function/or other additional or alternative functions. The configuring may be through at least one of firmware or software programming of the device, through at least one of a construction or layout of hardware components and interconnections of the device, or a combination thereof.

As used herein, the terms “terminal,” “node,” “interconnection,” “pin” and “lead” are used interchangeably. Unless specifically stated to the contrary, these terms are generally used to mean an interconnection between or a terminus of a device element, a circuit element, an integrated circuit, a device or other electronics or semiconductor component.

In the description and claims, described “circuitry” may include one or more circuits. A circuit or device that is described herein as including certain components may instead be adapted to be coupled to those components to form the described circuitry or device. For example, a structure described as including one or more semiconductor elements (such as transistors), one or more passive elements (such as one of or a combination of resistors, capacitors, or inductors), or one or more sources (such as voltage and/or current sources) may instead include only the semiconductor elements within a single physical device (e.g., at least one of a semiconductor die or integrated circuit (IC) package) and may be adapted to be coupled to at least some of the passive elements or the sources to form the described structure either at a time of manufacture or after a time of manufacture, for example, by at least one of an end-user or a third-party.

Circuits described herein are reconfigurable to include the replaced components to provide functionality at least partially similar to functionality available prior to the component replacement. Components shown as resistors, unless otherwise stated, are generally representative of any one or more elements coupled in at least one of series or parallel to provide an amount of impedance represented by the shown resistor. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor. While certain elements of the described examples are included in an integrated circuit and other elements are external to the integrated circuit, in other example embodiments, additional or fewer features may be incorporated into the integrated circuit. In addition, some or all of the features illustrated as being external to the integrated circuit may be included in the integrated circuit and some features illustrated as being internal to the integrated circuit may be incorporated outside of the integrated. As used herein, the term “integrated circuit” means one or more circuits that are at least one of: (i) incorporated in/over a semiconductor substrate; (ii) incorporated in a single semiconductor package; (iii) incorporated into the same module; or (iv) incorporated in/on the same printed circuit board.

Uses of the phrase “ground” in the foregoing description include at least one of a chassis ground, an Earth ground, a floating ground, a virtual ground, a digital ground, a common ground, or any other form of ground connection applicable to, or suitable for, the teachings of this description. Unless otherwise stated, “about,” “approximately,” or “substantially” preceding a value means +/−10 percent of the stated value, or, if the value is zero, a reasonable range of values around zero.

Modifications are possible in the described embodiments, and other embodiments are possible, within the scope of the claims.

What is claimed is:

1. An apparatus comprising:
filter circuitry having a first output and a second output;
source follower circuitry having a first input, a second input, and an output, the first input of the source follower circuitry coupled to the first output of the filter circuitry, the second input of the source follower circuitry coupled to the second output of the filter circuitry;
a resistor having a first terminal and a second terminal;
load circuitry having an input and an output, the input of the load circuitry coupled to the output of the source follower circuitry and the first terminal of the resistor; and
combination circuitry having a first input, and a second input, the first input of the combination circuitry coupled to the second terminal of the resistor, the second input of the combination circuitry coupled to the output of the load circuitry.

2. The apparatus of claim 1, wherein the filter circuitry further has a first input and a second input, and the apparatus further comprising alternating current (AC) coupler circuitry having a first output and a second output, the first output of the AC coupler circuitry coupled to the first input of the filter circuitry, the second output of the AC coupler circuitry coupled to the second input of the filter circuitry.

3. The apparatus of claim 2, wherein the resistor is a first resistor, and the AC coupler circuitry includes:
a first capacitor having a terminal;
a second capacitor having a terminal;
a second resistor having a first terminal and a second terminal; and
a third capacitor having a first terminal and a second terminal, the first terminal of the third capacitor coupled to the first input of the filter circuitry, the terminal of the first capacitor, the terminal of the second capacitor, and the first terminal of the second resistor, the second terminal of the third capacitor coupled to the second terminal of the second resistor.

4. The apparatus of claim 1, wherein the filter circuitry includes:
a first capacitor having a first terminal and a second terminal;
a first transistor having a first terminal, a second terminal, and a control terminal, the first terminal of the first transistor coupled to the first terminal of the first capacitor;
a second transistor having a first terminal, a second terminal, and a control terminal, the first terminal of the second transistor coupled to the second terminal of the first capacitor; and
a second capacitor having a first terminal and a second terminal, the first terminal of the second capacitor coupled to the first input of the source follower circuitry, the second terminal of the first transistor, and the control terminal of the second transistor, the second terminal of the second capacitor coupled to the second input of the source follower circuitry, the control terminal of the first transistor, and the second terminal of the second transistor.

5. The apparatus of claim 4, wherein the resistor is a first resistor, and the filter circuitry further includes:
a third transistor having a first terminal and a second terminal, the first terminal of the third transistor coupled to the first terminal of the first capacitor and the first terminal of the first transistor;
a fourth transistor having a first terminal and a second terminal, the first terminal of the fourth transistor coupled to the second terminal of the first capacitor and the first terminal of the second transistor;
a second resistor having a first terminal and a second terminal;
a fifth transistor having a first terminal and a control terminal, the first terminal of the fifth transistor coupled to the second terminal of the third transistor and the first terminal of the second resistor; and
a sixth transistor having a first terminal and a control terminal, the first terminal of the sixth transistor coupled to the second terminal of the fourth transistor and the second terminal of the second resistor, the control terminal of the sixth transistor coupled to the control terminal of the fifth transistor.

6. The apparatus of claim 1, wherein the resistor is a first resistor, and the source follower circuitry includes:
a first transistor having a first terminal and a control terminal, the control terminal of the first transistor coupled to the first output of the filter circuitry;
a second transistor having a first terminal and a control terminal, the control terminal of the second transistor coupled to the second output of the filter circuitry;
a third transistor having a first terminal, a second terminal, and a control terminal;
a fourth transistor having a first terminal, a second terminal, and a control terminal, the first terminal of the fourth transistor coupled to the first terminal of the second transistor and the control terminal of the third transistor, the control terminal of the fourth transistor is coupled to the first terminal of the first resistor, the input of the load circuitry, the first terminal of the first transistor, and the first terminal of the third transistor; and
a second resistor having a first terminal and a second terminal, the first terminal of the second resistor coupled to the second terminal of the third transistor, the second terminal of the second resistor coupled to the second terminal of the fourth transistor.

7. The apparatus of claim 6, wherein the source follower circuitry further includes:
a capacitor having a first terminal and a second terminal;
a fifth transistor having a first terminal and a control terminal, the first terminal of the fifth transistor coupled to the second terminal of the third transistor, the first terminal of the second resistor, and the first terminal of the capacitor; and
a sixth transistor having a first terminal and a control terminal, the first terminal of the sixth transistor coupled to the second terminal of the fourth transistor, the second terminal of the second resistor, and the second terminal of the capacitor, the control terminal of the sixth transistor coupled to the control terminal of the fifth transistor.

8. The apparatus of claim 1, wherein the resistor is a first resistor, the output of the source follower circuitry is a first output, the source follower circuitry further has a second output, the combination circuitry further has a third input, and the load circuitry includes:
a second resistor having a first terminal and a second terminal, the first terminal of the second resistor coupled to the first output of the source follower circuitry and the first terminal of the first resistor;
a third resistor having a first terminal and a second terminal, the first terminal of the third resistor coupled to the second output of the source follower circuitry; and
a fourth resistor having a first terminal and a second terminal, the first terminal of the fourth resistor coupled to the second terminal of the second resistor and the second input of the combination circuitry, the second terminal of the fourth resistor coupled to the second terminal of the third resistor and the third input of the combination circuitry.

9. The apparatus of claim 1, wherein the filter circuitry further has an input, the combination circuitry further has an output and the apparatus further comprising:
a communication channel having a terminal coupled to the second terminal of the resistor and the first input of the combination circuitry;
serializer circuitry having an output coupled to the input of the filter circuitry; and
receiver circuitry having an input coupled to the output of the combination circuitry.

10. The apparatus of claim 9, wherein the terminal of the communication channel is a first terminal, the communication channel further has a second terminal, the receiver circuitry is first receiver circuitry, and the apparatus further comprising:
transmitter circuitry having an output; and
second receiver circuitry having an input coupled to the second terminal of the communication channel and the output of the transmitter circuitry.

11. An apparatus comprising:
receiver circuitry having an input;
transmitter circuitry having a first output, a second output, a third output, and a fourth output; and
echo cancelation circuitry including:
load circuitry having a first input, a second input, a first output and a second output, the first input of the load circuitry coupled to the first output of the transmitter circuitry, the second input of the load circuitry coupled to the second output of the transmitter circuitry; and
combination circuitry having a first input, a second input, a third input, a fourth input, and an output, the first input of the combination circuitry coupled to the third output of the transmitter circuitry, the second input of the combination circuitry coupled to the fourth output of the transmitter circuitry, the third input of the combination circuitry coupled to the first output of the load circuitry, the fourth input of the combination circuitry coupled to the second output of the load circuitry, the output of the combination circuitry coupled to the input of the receiver circuitry.

12. The apparatus of claim 11, wherein the transmitter circuitry includes:
filter circuitry having a first output and a second output;
source follower circuitry having a first input, a second input, a first output, and a second output, the first input of the source follower circuitry coupled to the first output of the filter circuitry, the second input of the source follower circuitry coupled to the second output of the filter circuitry;
a first resistor having a first terminal and a second terminal, the first terminal of the first resistor coupled to the first input of the load circuitry and the first output of the source follower circuitry, the second terminal of the first resistor coupled to the first input of the combination circuitry; and
a second resistor having a first terminal and a second terminal, the first terminal of the second resistor coupled to the second input of the load circuitry and the second output of the source follower circuitry, the second terminal of the second resistor coupled to the second input of the combination circuitry.

13. The apparatus of claim 12, wherein the filter circuitry further has a first input and a second input, and the apparatus further comprising alternating current (AC) coupler circuitry having a first output and a second output, the first output of the AC coupler circuitry coupled to the first input of the filter circuitry, the second output of the AC coupler circuitry coupled to the second input of the filter circuitry.

14. The apparatus of claim 12, wherein the filter circuitry includes:
a first capacitor having a first terminal and a second terminal;
a first transistor having a first terminal, a second terminal, and a control terminal, the first terminal of the first transistor coupled to the first terminal of the first capacitor;
a second transistor having a first terminal, a second terminal, and a control terminal, the first terminal of the second transistor coupled to the second terminal of the first capacitor; and
a second capacitor having a first terminal and a second terminal, the first terminal of the second capacitor coupled to the first input of the source follower circuitry, the second terminal of the first transistor, and the control terminal of the second transistor, the second terminal of the second capacitor coupled to the second input of the source follower circuitry, the control terminal of the first transistor, and the second terminal of the second transistor.

15. The apparatus of claim 12, and the source follower circuitry includes:
a first transistor having a first terminal and a control terminal, the control terminal of the first transistor coupled to the first output of the filter circuitry;
a second transistor having a first terminal and a control terminal, the control terminal of the second transistor coupled to the second output of the filter circuitry;
a third transistor having a first terminal, a second terminal, and a control terminal;
a fourth transistor having a first terminal, a second terminal, and a control terminal, the first terminal of the fourth transistor coupled to the first terminal of the second transistor and the control terminal of the third transistor, the control terminal of the fourth transistor is coupled to the first terminal of the first resistor, the input of the load circuitry, the first terminal of the first transistor, and the first terminal of the third transistor; and
a resistor having a first terminal and a second terminal, the first terminal of the resistor coupled to the second terminal of the third transistor, the second terminal of the resistor coupled to the second terminal of the fourth transistor.

16. The apparatus of claim 11, wherein the load circuitry includes:
a first resistor having a first terminal and a second terminal, the first terminal of the first resistor coupled to the first output of the transmitter circuitry;
a second resistor having a first terminal and a second terminal, the first terminal of the second resistor coupled to the second output of the transmitter circuitry; and
a third resistor having a first terminal and a second terminal, the first terminal of the third resistor coupled to the second terminal of the first resistor and the third input of the combination circuitry, the second terminal of the third resistor coupled to the second terminal of the second resistor and the fourth input of the combination circuitry.

17. The apparatus of claim 11, wherein the transmitter circuitry is first transmitter circuitry, the receiver circuitry is first receiver circuitry, and the apparatus further comprising:
a communication channel having a first terminal and a second terminal, the first terminal of the communication channel coupled to the third output of the first transmitter circuitry and the first input of the combination circuitry;
second transmitter circuitry having an output; and
second receiver circuitry having an input coupled to the second terminal of the communication channel and the output of the second transmitter circuitry.

18. An apparatus comprising:
first transmitter circuitry having an output;
a communication channel having a first terminal and a second terminal, the first terminal of the communication channel coupled to the output of the first transmitter circuitry;
second transmitter circuitry having a first output and a second output;
echo cancelation circuitry having a first input, a second input, and an output, the first input of the echo cancelation circuitry coupled to the first output of the second transmitter circuitry, the second input of the echo cancelation circuitry coupled to the second terminal of the communication channel and the second output of the second transmitter circuitry; and
receiver circuitry having an input coupled to the output of the echo cancelation circuitry.

19. The apparatus of claim 18, wherein the echo cancelation circuitry further has a third input and a fourth input, and further comprising:
the second transmitter circuitry includes:
filter circuitry having a first output and a second output;
source follower circuitry having a first input, a second input, a first output, and a second output, the first input of the source follower circuitry coupled to the first output of the filter circuitry, the second input of the source follower circuitry coupled to the second output of the filter circuitry;
a first resistor having a first terminal and a second terminal, the first terminal of the first resistor coupled to the second terminal of the communication channel, the first input of the echo cancelation circuitry, and the first output of the source follower circuitry, the second terminal of the first resistor coupled to the second input of the echo cancelation circuitry; and
a second resistor having a first terminal and a second terminal, the first terminal of the second resistor coupled to the third input of the echo cancelation circuitry and the second output of the source follower circuitry, the second terminal of the second resistor coupled to the fourth input of the echo cancelation circuitry; and
the echo cancelation circuitry includes:
load circuitry having an input and an output, the input of the load circuitry coupled to the first output of the second transmitter circuitry; and
combination circuitry having a first input, a second input, and an output, the first input of the combination circuitry coupled to the second terminal of the communication channel and the second output of the second transmitter circuitry, the second input of the combination circuitry coupled to the output of the load circuitry, and the output of the combination circuitry coupled to the input of the receiver circuitry.

20. The apparatus of claim 18, wherein the first transmitter circuitry includes:
a first feed-forward equalization (FFE) segment having an output;
a second FFE segment having an output; and
impedance compensation circuitry having an input and an output, the input of the impedance compensation circuitry coupled to the output of the first FFE segment and the output of the second FFE segment, the output of the impedance compensation circuitry coupled to the first terminal of the communication channel.

21. The apparatus of claim 20, wherein the first FFE segment includes:
an amplifier having an output;
a first capacitor having a first terminal and a second terminal, the first terminal of the first capacitor coupled to the output of the amplifier;
a second capacitor having a terminal; and
a transistor having a first terminal and a control terminal, the first terminal of the transistor coupled to the output of the second FFE segment and the input of the impedance compensation circuitry, the control terminal of the transistor coupled to the second terminal of the first capacitor and the terminal of the second capacitor.

22. The apparatus of claim 20, wherein the output of the first FFE segment is a first output, the first FFE segment further having a second output, the output of the second FFE segment is a first output, the second FFE segment further having a second output, and the impedance compensation circuitry includes:
a capacitor having a first terminal and a second terminal;
a first transistor having a first terminal, a second terminal, and a control terminal, the first terminal of the first transistor coupled to the first output of the first FFE segment, the first output of the second FFE segment, and the first terminal of the capacitor; and
a second transistor having a first terminal, a second terminal, and a control terminal, the first terminal of the second transistor coupled to the second output of the first FFE segment, the second output of the second FFE segment, and the second terminal of the capacitor, the second terminal of the second transistor coupled to the control terminal of the first transistor, the control terminal of the second transistor coupled to the first terminal of the communication channel and the second terminal of the first transistor.
